(19) United States
(12) Patent Application Publication
(10) Pub. No.: US 2023/0262959 A1
(43) Pub. Date: Aug. 17, 2023

(54) SEMICONDUCTOR MEMORY DEVICE

(71) Applicant: SAMSUNG ELECTRONICS CO., LTD., Suwon-si (KR)

(72) Inventors: Jungmin PARK, Seoul (KR); Hanjin LIM, Seoul (KR)

(21) Appl. No.: 18/076,599

(22) Filed: Dec. 7, 2022

(30) Foreign Application Priority Data
Feb. 16, 2022 (KR) 10-2022-0020398

(51) Int. Cl. H01L 29/94

(52) U.S. Cl. CPC H01L 27/10814; H01L 27/10885; H01L 27/10823; H01L 27/10855; H01L 27/10876

(57) ABSTRACT

A semiconductor memory device includes a substrate, and a capacitor structure on the substrate and including a lower electrode, a capacitor dielectric layer, and an upper electrode, wherein the capacitor dielectric layer includes a lower interface layer on the lower electrode and doped with impurities of a first conductive type, an upper interface layer beneath the upper electrode and doped with impurities of a second conductive type other than the first conductive type, and a dielectric structure between the lower interface layer and the upper interface layer.

### CROSS-REFERENCE TO RELATED APPLICATION

This application is based on and claims priority under 35 U.S.C. § 119 to Korean Patent Application No. 10-2022-0020398, filed on Feb. 16, 2022, in the Korean Intellectual Property Office, the disclosure of which is incorporated by reference herein in its entirety.

### BACKGROUND

### 1. Field

Embodiments relate to a semiconductor memory device, and more particularly, to a semiconductor memory device having a capacitor structure.

### 2. Description of the Related Art

Along with the rapid development of the electronics industry and requests of users, electronic devices have been miniaturized and made lightweight. Accordingly, because a high degree of integration is also required for semiconductor memory devices used in electronic devices, the design rules for components in the semiconductor memory devices are reduced, thereby achieving microstructures. In addition, a semiconductor memory device having a capacitor structure requires high capacity with the microstructure.

### SUMMARY

According to an aspect of embodiments, there is provided a semiconductor memory device including a substrate; and a capacitor structure disposed on the substrate and including a lower electrode, a capacitor dielectric layer, and an upper electrode, wherein the capacitor dielectric layer includes: a lower interface layer disposed on the lower electrode and doped with impurities of a first conductive type; an upper interface layer disposed beneath the upper electrode and doped with impurities of a second conductive type other than the first conductive type; and a dielectric structure between the lower interface layer and the upper interface layer.

According to another aspect of embodiments, there is provided a semiconductor memory device including a substrate having a memory cell region; and a plurality of capacitor structures disposed in the memory cell region of the substrate and including a plurality of lower electrodes, an upper electrode, and a capacitor dielectric layer between the plurality of lower electrodes and the upper electrode, wherein the capacitor dielectric layer includes, a lower interface layer doped with impurities of a first conductive type, a lower dielectric layer, an insertion layer, an upper dielectric layer, and an upper interface layer doped with impurities of a second conductive type other than the first conductive type, which are sequentially stacked on the lower electrode, and a bandgap of the insertion layer is greater than each of a bandgap of the lower dielectric layer and a bandgap of the upper dielectric layer.

According to yet another aspect of embodiments, there is provided a semiconductor memory device including a substrate having a plurality of active regions in a memory cell region; a plurality of buried contacts connected to the plurality of active regions; a plurality of landing pads on the plurality of buried contacts; and a plurality of capacitor structures disposed in the memory cell region of the substrate and including a plurality of lower electrodes electrically connected to the plurality of landing pads, an upper electrode, and a capacitor dielectric layer between the plurality of lower electrodes and the upper electrode, wherein the capacitor dielectric layer includes a lower interface layer that is a metal oxide doped with n-type impurities that are metal atoms, a lower dielectric layer, an insertion layer, an upper dielectric layer, and an upper interface layer that is a metal oxide doped with p-type impurities that are metal atoms, which are sequentially stacked on the lower electrode, a thickness of the lower interface layer is greater than a thickness of the upper interface layer, and a thickness of the insertion layer is less than the thickness of the upper interface layer.

### BRIEF DESCRIPTION OF THE DRAWINGS

Features will become apparent to those of skill in the art by describing in detail exemplary embodiments with reference to the attached drawings, in which:

FIG. 1 is a layout diagram of a semiconductor memory device according to embodiments;

FIG. 2 is a schematic planar layout diagram of main components of a semiconductor memory device according to embodiments;

FIGS. 3A to 3D are cross-sectional views illustrating a semiconductor memory device according to embodiments;

FIGS. 4A to 4C are cross-sectional views illustrating a capacitor structure in a semiconductor memory device, according to embodiments;

FIGS. 5A to 5D, 6A to 6D, 7A to 7D, 8A to 8D, and 9A to 9D are cross-sectional views of stages in a method of manufacturing a semiconductor memory device, according to embodiments;

FIG. 10 is a conceptual diagram of an operation of a semiconductor memory device according to embodiments;

FIG. 11 is a layout diagram illustrating a semiconductor memory device according to embodiments;

FIG. 12 is a cross-sectional view along lines X1-X1′ and Y1-Y1′ of FIG. 11;

FIGS. 13A to 13C are cross-sectional views illustrating a capacitor structure in a semiconductor memory device, according to embodiments; and

FIG. 14 is a layout diagram illustrating a semiconductor memory device according to embodiments; and

FIG. 15 is a perspective view of a semiconductor memory device according to embodiments.

### DETAILED DESCRIPTION

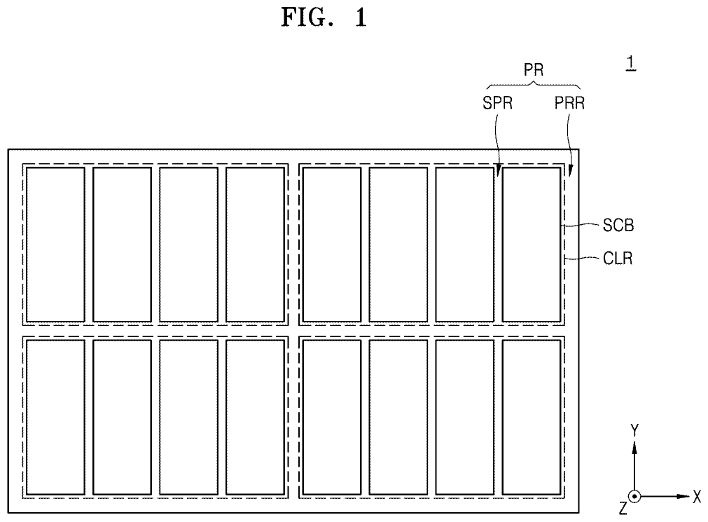

FIG. 1 is a layout diagram of a semiconductor memory device 1 according to embodiments. Referring to FIG. 1, the semiconductor memory device 1 may include cell regions CLR in which memory cells are arranged and a main peripheral region PRR surrounding the cell regions CLR.

According to an embodiment, the cell region CLR may include sub-peripheral regions SPR for identifying cell blocks SCB. A plurality of memory cells may be arranged in the cell blocks SCB. In the specification, the term “cell block SCB” indicates a region in which memory cells are regularly arranged at uniform intervals therebetween, and the cell block SCB may be called a sub-cell block.

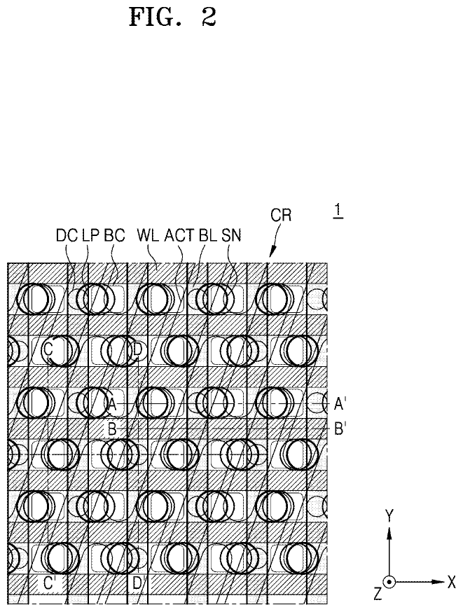

In the main peripheral region PRR and the sub-peripheral regions SPR, logic cells for inputting/outputting an electrical signal to/from the plurality of memory cells may be arranged. In some embodiments, the main peripheral region PRR may be called a peripheral circuit region, and the sub-peripheral regions SPR may be called a core circuit region. A peripheral region PR may include the main peripheral region PRR and the sub-peripheral regions SPR. That is, the peripheral region PR may be core and peripheral circuit region including the peripheral circuit region and the core circuit region. In some embodiments, at least some of the sub-peripheral regions SPR may be provided as spaces for identifying the cell blocks SCB. For example, the cell blocks SCB may be regions shown in FIGS. 2 to 15.

FIG. 2 is a schematic planar layout diagram of main components of the semiconductor memory device 1 according to embodiments.

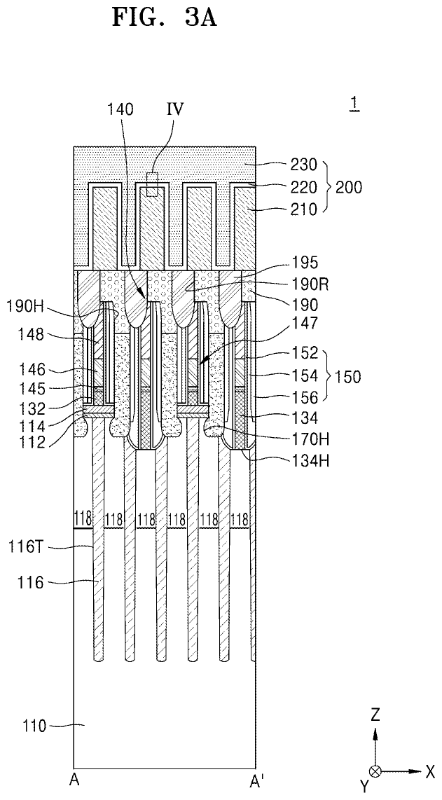

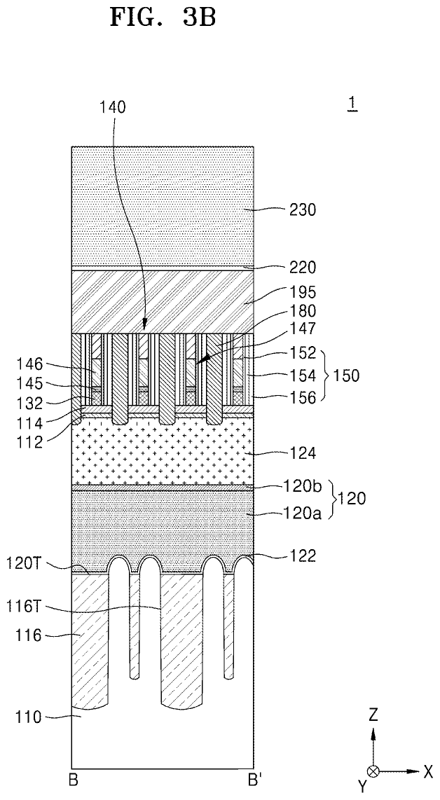

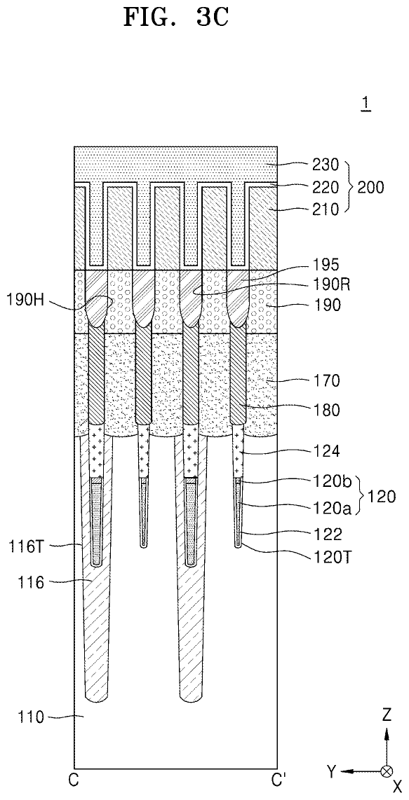

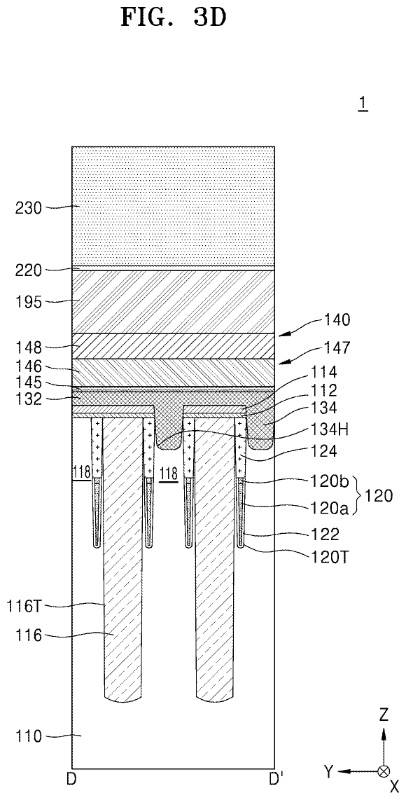

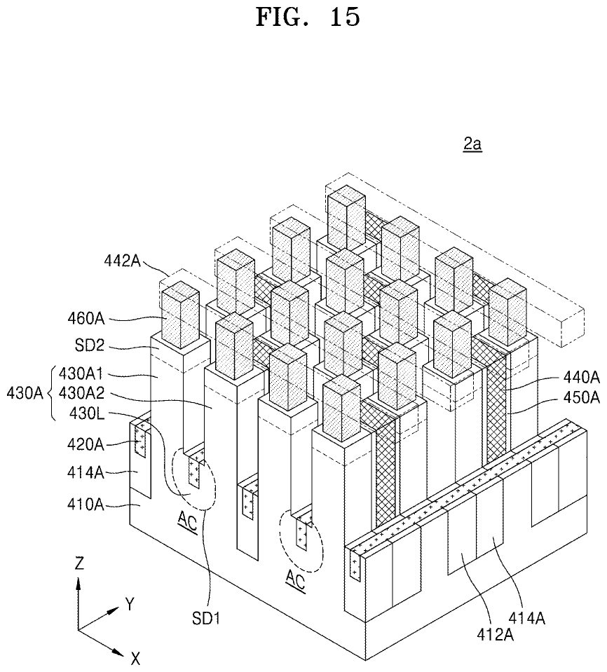

Referring to FIG. 2, the semiconductor memory device 1 may include a plurality of active regions ACT formed in a memory cell region CR. In some embodiments, the active regions ACT in the memory cell region CR may be arranged to have a long axis in a diagonal direction with respect to a first horizontal direction (an X direction) and a second horizontal direction (a Y direction). The active regions ACT may form a plurality of active regions 118 shown in FIGS. 3A to 3D, 4A to 4D, 5A to 5D, 6A to 6D, 7A to 7D, 8A to 8D, and 9A to 9D or a plurality of active regions AC shown in FIG. 15.

A plurality of word lines WL may extend in parallel to each other in the first horizontal direction (the X direction) by crossing the plurality of active regions ACT. On the plurality of word lines WL, a plurality of bit lines BL may extend in parallel to each other in the second horizontal direction (the Y direction) intersecting with the first horizontal direction (the X direction).

In some embodiments, a plurality of buried contacts BC may be formed between, e.g., every two, adjacent bit lines BL. In some embodiments, the buried contacts BC may be arranged in lines in each of the first horizontal direction (the X direction) and the second horizontal direction (the Y direction).

A plurality of landing pads LP may be formed on the plurality of buried contacts BC. The plurality of landing pads LP may at least partially overlap the plurality of buried contacts BC. In some embodiments, each of the plurality of landing pads LP may extend onto any one of two adjacent bit lines BL.

A plurality of storage nodes SN may be respectively formed on the plurality of landing pads LP. The plurality of storage nodes SN may be respectively formed above the plurality of bit lines BL. The storage nodes SN may be lower electrodes of a plurality of capacitors, respectively. A storage node SN may be connected to an active region ACT via a landing pad LP and a buried contact BC. For example, the semiconductor memory device 1 may be a dynamic random access memory (DRAM) device.

FIGS. 3A to 3D are cross-sectional views illustrating the semiconductor memory device 1 according to embodiments. FIGS. 3A, 3B, 3C, and 3D are cross-sectional views taken along lines A-A′, B-B′, C-C′, and D-D′ of FIG. 2, respectively.

Referring to FIGS. 3A to 3D, the semiconductor memory device 1 may include a substrate 110 with the plurality of active regions 118 defined by a device isolation layer 116, and having a plurality of word line trenches 120T crossing the plurality of active regions 118, a plurality of word lines 120 inside the plurality of word line trenches 120T, a plurality of bit line structures 140, and a plurality of capacitor structures 200 with a plurality of lower electrodes 210, a capacitor dielectric layer 220, and an upper electrode 230.

The substrate 110 may include, e.g., silicon (Si), crystalline Si, polycrystalline Si, or amorphous Si. In other some embodiments, the substrate 110 may include a semiconductor element, e.g., germanium (Ge), or at least one compound semiconductor, e.g., SiGe, silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide (BOX) layer. The substrate 110 may include a conductive region, e.g., an impurity-doped well or an impurity-doped structure.

The plurality of active regions 118 may be a portion of the substrate 110 limited by a device isolation trench 116T. The plurality of active regions 118 may have a relatively long island shape having a short axis and a long axis in a top view. In some embodiments, the plurality of active regions 118 may be arranged to have the long axis in a diagonal direction with respect to the first horizontal direction (the X direction) and the second horizontal direction (the Y direction). The plurality of active regions 118 may extend in a long axis direction with generally the same lengths and be repeatedly arranged with generally the same pitch therebetween.

The device isolation layer 116 may fill the device isolation trench 116T. The plurality of active regions 118 may be defined in the substrate 110 by the device isolation layer 116.

In some embodiments, the device isolation layer 116 may include a triple layer including a first device isolation layer, a second device isolation layer, and a third device isolation layer. For example, the first device isolation layer may conformally cover an inner side surface and a bottom surface of the device isolation trench 116T. In some embodiments, the first device isolation layer may include silicon oxide (SiO). For example, the second device isolation layer may conformally cover the first device isolation layer. In some embodiments, the second device isolation layer may include silicon nitride (SiN). For example, the third device isolation layer may cover the second device isolation layer and fill the device isolation trench 116T. In some embodiments, the third device isolation layer may include SiO. For example, the third device isolation layer may include SiO including Tonen Silazene (TOSZ). In some embodiments, the device isolation layer 116 may be formed by a single layer including one type of insulating layer, a double layer including two types of insulating layers, or a multi-layer including a combination of at least four types of insulating layers. For example, the device isolation layer 116 may be formed by a single layer including SiO.

The plurality of word line trenches 120T may be formed in the substrate 110 including the plurality of active regions 118 defined by the device isolation layer 116. The plurality of word line trenches 120T may have line shapes extending in the first horizontal direction (the X direction) to be parallel to each other, and arranged to have generally equal intervals in the second horizontal direction (the Y direction) with each word line trench 120T crossing the active region 118. In some embodiments, stepped portions may be formed on bottom surfaces of the word line trenches 120T, respectively.

In the insides of the plurality of word line trenches 120T, a plurality of gate dielectric layers 122, the plurality of word lines 120, and a plurality of buried insulating layers 124 may be sequentially formed, respectively. The plurality of word lines 120 may form the plurality of word lines WL shown in FIG. 2. The plurality of word lines 120 may have line shapes extending in the first horizontal direction to be parallel to each other, and arranged to have generally equal intervals in the second horizontal direction with each word line 120 crossing the active region 118. The upper surface of each of the plurality of word lines 120 may be at a vertical level that is lower than the upper surface of the substrate 110. Lower surfaces of the plurality of word lines 120 may have a concave-convex shape, and saddle fin-structured field effect transistors (saddle Fin FETs) may be formed in the plurality of active regions 118, respectively.

In the specification, the term “level” or “vertical level” indicates a height in a vertical direction (a Z direction) with respect to a main surface or the upper surface of the substrate 110. That is, being at the same level or a certain level indicates being at the same height or a certain height in the vertical direction (the Z direction) with respect to the main surface or the upper surface of the substrate 110, and being at a lower/higher vertical level indicates being at a lower/higher height in the vertical direction (the Z direction) with respect to the main surface or the upper surface of the substrate 110.

The plurality of word lines 120 may fill lower portions of the plurality of word line trenches 120T, respectively. Each of the plurality of word lines 120 may have a stack structure including a lower word line layer 120a and an upper word line layer 120b. For example, the lower word line layer 120a may conformally cover an inner side wall and the bottom surface of the lower portion of the word line trench 120T with the gate dielectric layer 122 therebetween. For example, the upper word line layer 120b may cover the lower word line layer 120a and fill the lower portion of the word line trench 120T with the gate dielectric layer 122 therebetween. For example, the lower word line layer 120a may include a metal material or a conductive metal nitride, e.g., titanium (Ti), titanium nitride (TiN), tantalum (Ta), or tantalum nitride (TaN). For example, the upper word line layer 120b may include a doped polysilicon, a metal material, e.g., tungsten (W), a conductive metal nitride, e.g., tungsten nitride (WN), titanium silicon nitride (TiSiN), or tungsten silicon nitride (WSiN), or a combination thereof. In portions of active regions 118 of the substrate 110 at both sides of each of the plurality of word lines 120, a source region and a drain region may be respectively formed by injecting impurity ions to the portions of the active regions 118.

The gate dielectric layer 122 may cover the inner side wall and the bottom surface of the word line trench 120T. In some embodiments, the gate dielectric layer 122 may extend from between the word line 120 and the word line trench 120T to between a buried insulating layer 124 and the word line trench 120T. The gate dielectric layer 122 may include at least one of SiO, SiN, silicon oxynitride, oxide/nitride/oxide (ONO), and a high-k dielectric material having a higher dielectric constant than SiO. For example, the gate dielectric layer 122 may have a dielectric constant of about 10 to about 25. In some embodiments, the gate dielectric layer 122 may include at least one of hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric layer 122 may include hafnium dioxide (HfO₂), aluminum trioxide (Al₂O₃), hafnium aluminum trioxide (HfAlO₃), tantalum trioxide (Ta₂O₃), or titanium dioxide (TiO₂).

The plurality of buried insulating layers 124 may fill upper portions of the plurality of word line trenches 120T, respectively. In some embodiments, upper surfaces of the plurality of buried insulating layers 124 may be at substantially the same vertical level as the upper surface of the substrate 110. The buried insulating layer 124 may include at least one of SiO, SiN, silicon oxynitride, and a combination thereof. For example, the buried insulating layer 124 may include SiN.

Insulating layer patterns may be on the device isolation layer 116, the plurality of active regions 118, and the plurality of buried insulating layers 124. For example, the insulating layer patterns may include SiO, SiN, silicon oxynitride, a metal-based dielectric material, or a combination thereof In some embodiments, the insulating layer patterns may include a first insulating layer pattern 112 and a second insulating layer pattern 114. For example, the insulating layer patterns have a stack structure of the first insulating layer pattern 112 and the second insulating layer pattern 114 on the first insulating layer pattern 112. In some embodiments, the first insulating layer pattern 112 may include SiO, and the second insulating layer pattern 114 may include silicon oxynitride. In other some embodiments, the first insulating layer pattern 112 may include a non-metal-based dielectric material, and the second insulating layer pattern 114 may include a metal-based dielectric material. In some embodiments, the second insulating layer pattern 114 may be thicker than the first insulating layer pattern 112. For example, the first insulating layer pattern 112 may have a thickness of about 50 Å to about 90 Å, and the second insulating layer pattern 114 may be thicker than the first insulating layer pattern 112 and have a thickness of about 60 Å to about 100 Å.

A plurality of direct contact conductive patterns 134 may respectively fill portions of a plurality of direct contact holes 134H, each passing through the insulating layer patterns to exposure a source region in the active region 118. For example, the direct contact hole 134H may extend to the inside of the active region 118, i.e., the inside of the source region. The direct contact conductive pattern 134 may include, e.g., doped polysilicon. In some embodiments, the direct contact conductive pattern 134 may include an epitaxial silicon layer. The plurality of direct contact conductive patterns 134 may respectively form a plurality of direct contacts DC shown in FIG. 2.

The plurality of bit line structures 140 may be on the insulating layer patterns. Each of the plurality of bit line structures 140 may include a bit line 147 and an insulating capping line 148 covering the bit line 147. The plurality of bit line structures 140 may extend in the second horizontal direction (the Y direction) that is parallel to the main surface of the substrate 110 to be parallel to each other. A plurality of bit lines 147 may respectively form the plurality of bit lines BL shown in FIG. 2. The plurality of bit lines 147 may be electrically connected to the plurality of active regions 118 via the plurality of direct contact conductive patterns 134, respectively. In some embodiments, the bit line structure 140 may further include a conductive semiconductor pattern 132 between the insulating layer patterns and the bit line structure 140. The conductive semiconductor pattern 132 may include, e.g., doped polysilicon.

The bit line 147 may have a stack structure including a first metal-based conductive pattern 145 and a second metal-based conductive pattern 146, which have a line shape. In some embodiments, the first metal-based conductive pattern 145 may include TiN or titanium silicon nitride (Ti—Si—N (TSN)), and the second metal-based conductive pattern 146 may include tungsten (W) or W and tungsten silicide (WSiₓ). In some embodiments, the first metal-based conductive pattern 145 may function as a diffusion barrier. For example, the insulating capping lines 148 may include SiN.

A plurality of insulating spacer structures 150 may cover both side walls of the plurality of bit line structures 140. Each of the plurality of insulating spacer structures 150 may include a first insulating spacer 152, a second insulating spacer 154, and a third insulating spacer 156. In some embodiments, the plurality of insulating spacer structures 150 may respectively extend to the inside of the plurality of direct contact holes 134H and cover both side walls of the plurality of direct contact conductive patterns 134. The second insulating spacer 154 may include a material having a lower dielectric constant than a dielectric constant of the first insulating spacer 152 and a dielectric constant of the third insulating spacer 156. For example, the first insulating spacer 152 and the third insulating spacer 156 may include nitride, and the second insulating spacer 154 may include oxide. In another example, the first insulating spacer 152 and the third insulating spacer 156 may include nitride, and the second insulating spacer 154 may include a material having an etching selectivity with respect to the first insulating spacer 152 and the third insulating spacer 156. For example, the first insulating spacer 152 and the third insulating spacer 156 may include nitride, and the second insulating spacer 154 may include an air spacer. In some embodiments, the insulating spacer structure 150 may include the second insulating spacer 154 including oxide and the third insulating spacer 156 including nitride.

Each of a plurality of insulating fences 180 may be in a space between a pair of insulating spacer structures 150 facing each other between a pair of adjacent bit line structures 140. The plurality of insulating fences 180 may be separated from each other to form lines between every pair of insulating spacer structures 150 facing each other, i.e., in the second horizontal direction (the Y direction). For example, the plurality of insulating fences 180 may include nitride.

For example, the plurality of insulating fences 180 may be formed to extend to the inside of the buried insulating layer 124 by passing through the insulating layer patterns. In another example, the plurality of insulating fences 180 may be formed to pass through the insulating layer patterns but not to extend to the inside of the buried insulating layer 124, to extend to the inside of the buried insulating layer 124 but not to pass through the insulating layer patterns, or not to extend to the inside of the buried insulating layer 124 so that lower surfaces of the plurality of insulating fences 180 are in contact with the insulating layer patterns.

Between every two of the plurality of bit lines 147, a plurality of buried contact holes 170H may be limited between the plurality of insulating fences 180, respectively. The plurality of buried contact holes 170H and the plurality of insulating fences 180 may be alternately arranged between every pair of insulating spacer structures 150 facing each other among the plurality of insulating spacer structures 150 covering both side walls of the plurality of bit line structures 140, i.e., in the second horizontal direction (the Y direction). Each of the plurality of buried contact holes 170H may have an internal space limited by the insulating fence 180, the active region 118, and the insulating spacer structure 150 covering a side wall of each of two neighboring bit lines 147 between the two neighboring bit lines 147 among the plurality of bit lines 147. For example, each of the plurality of buried contact holes 170H may extend to the inside of the active region 118 from between the insulating spacer structure 150 and the insulating fence 180.

A plurality of buried contacts 170 may be inside the plurality of buried contact holes 170H, respectively. The plurality of buried contacts 170 may respectively fill lower portions of spaces between the plurality of insulating fences 180 and the plurality of insulating spacer structures 150 covering both side walls of the plurality of bit line structures 140. The plurality of buried contacts 170 and the plurality of insulating fences 180 may be alternately arranged between every pair of insulating spacer structures 150 facing each other among the plurality of insulating spacer structures 150 covering both side walls of the plurality of bit line structures 140, i.e., in the second horizontal direction. For example, the plurality of buried contacts 170 may include polysilicon.

In some embodiments, the plurality of buried contacts 170 may be arranged in lines in each of the first horizontal direction (the X direction) and the second horizontal direction (the Y direction). Each of the plurality of buried contacts 170 may extend from the active region 118 in the vertical direction (the z direction) that is perpendicular to the substrate 110. The plurality of buried contacts 170 may form the plurality of buried contacts BC shown in FIG. 2.

Levels of upper surfaces of the plurality of buried contacts 170 may be lower than levels of upper surfaces of the plurality of insulating capping lines 148. Upper surfaces of the plurality of insulating fences 180 and the upper surfaces of the plurality of insulating capping lines 148 may be at the same vertical level in the vertical direction.

A plurality of landing pad holes 190H may be limited by the plurality of buried contacts 170, the plurality of insulating spacer structures 150, and the plurality of insulating fences 180. The plurality of buried contacts 170 may be exposed at bottom surfaces of the plurality of landing pad holes 190H.

A plurality of landing pads 190 may fill at least portions of the plurality of landing pad holes 190H and extend above the plurality of bit line structures 140. The plurality of landing pads 190 may be separated from each other by recess parts 190R. Each of the plurality of landing pads 190 may include a conductive barrier layer and a conductive pad material layer on the conductive barrier layer. For example, the conductive barrier layer may include a metal, conductive metal nitride, or a combination thereof. In some embodiments, the conductive barrier layer may have a stack structure including Ti/TiN. In some embodiments, the conductive pad material layer may include W. In some embodiments, a metal silicide layer may be formed between the landing pad 190 and the buried contact 170. The metal silicide layer may include, e.g., cobalt silicide (CoSiₓ), nickel silicide (NiSiₓ), or manganese silicide (MnSiₓ).

The plurality of landing pads 190 may be on the plurality of buried contacts 170, and may be electrically connected to the plurality of buried contacts 170, respectively. The plurality of landing pads 190 may be connected to the plurality of active regions 118 via the plurality of buried contacts 170, respectively. The plurality of landing pads 190 may form the plurality of landing pads LP shown in FIG. 2. The buried contact 170 may be between two adjacent bit line structures 140, and the landing pad 190 may extend onto one bit line structure 140 from between the two adjacent bit line structures 140 with the buried contact 170 therebetween.

The recess parts 190R may be filled with an insulating structure 195. In some embodiments, the insulating structure 195 may include an interlayer insulating layer and an etching stop layer. For example, the interlayer insulating layer may include oxide, and the etching stop layer may include nitride. For example, the etching stop layer may include SiN or silicon boron nitride (SiBN). For example, as illustrated in FIGS. 3A and 3C, the upper surface of the insulating structure 195 and upper surfaces of the plurality of landing pads 190 may be at the same vertical level. In another example, the insulating structure 195 may have an upper surface at a higher vertical level than the upper surfaces of the plurality of landing pads 190 by filling the recess parts 190R and covering the upper surfaces of the plurality of landing pads 190.

The plurality of capacitor structures 200 including the plurality of lower electrodes 210, the capacitor dielectric layer 220, and the upper electrode 230 may be on the plurality of landing pads 190 and the insulating structure 195. The lower electrode 210 and the landing pad 190 corresponding to each other may be electrically connected to each other. For example, as illustrated in FIGS. 3A and 3C, the upper surface of the insulating structure 195 and the lower surface of the lower electrode 210 may be at the same vertical level. The plurality of lower electrodes 210 may form the plurality of storage nodes SN shown in FIG. 2.

In some embodiments, the semiconductor memory device 1 may further include at least one support pattern supporting the plurality of lower electrodes 210 by being in contact with side walls of the plurality of lower electrodes 210. The at least one support pattern may include, e.g., at least one of SiN, silicon carbon nitride (SiCN), N-rich SiN, and Si-rich SiN. In some embodiments, the at least one support pattern may include a plurality of support patterns in contact with the side walls of the plurality of lower electrodes 210 and at different vertical levels so as to be separated from each other in the vertical direction (the z direction).

Each of the plurality of lower electrodes 210 may have a pillar shape with the inside filled to have a circular horizontal cross-section. In some embodiments, each of the plurality of lower electrodes 210 may have a cylindrical shape with a closed bottom. For example, the plurality of lower electrodes 210 may be in a honeycomb shape arranged in a zigzag pattern in the first horizontal direction (the X direction) or the second horizontal direction (the Y direction). In another example, the plurality of lower electrodes 210 may be in a matrix shape arranged in lines in each of the first horizontal direction (the X direction) and the second horizontal direction (the Y direction). For example, the plurality of lower electrodes 210 may include impurity-doped silicon, a metal, e.g., W or copper, or a conductive metal compound, e.g., TiN. In another example, the plurality of lower electrodes 210 may include TiN, chromium nitride (CrN), vanadium nitride (VN), molybdenum nitride (MoN), niobium nitride (NbN), TiSiN, titanium aluminum nitride (TiAlN), or tantalum aluminum nitride (TaAlN).

The capacitor dielectric layer 220 may conformally cover the surfaces of the plurality of lower electrodes 210. In some embodiments, the capacitor dielectric layer 220 may be formed as one body to conformally cover the surfaces of the plurality of lower electrodes 210 in a certain region, e.g., one memory cell region CR (see FIG. 2).

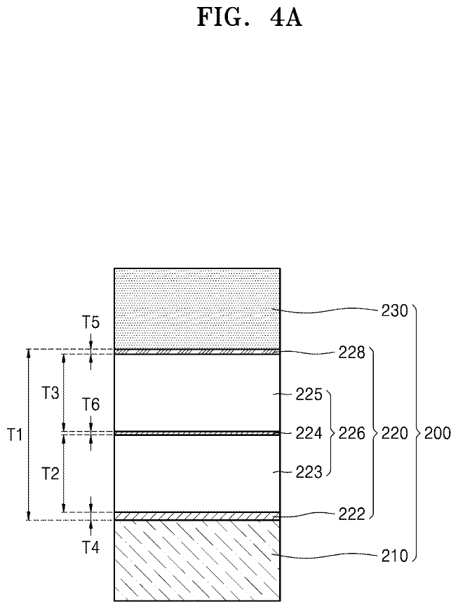

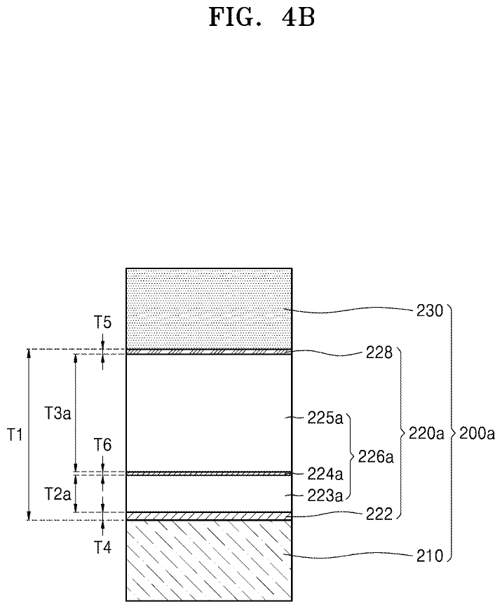

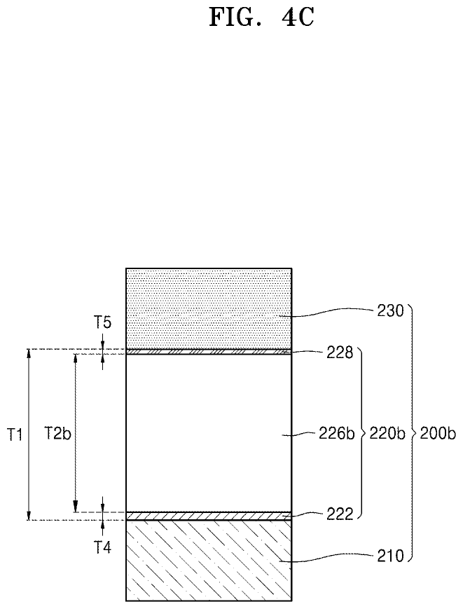

The capacitor dielectric layer 220 may include a material having an antiferroelectricity characteristic, a material having a ferroelectricity characteristic, or a material in which the antiferroelectricity characteristic is combined with the ferroelectricity characteristic. For example, the capacitor dielectric layer 220 may include SiO, metal oxide, or a combination thereof. In some embodiments, the capacitor dielectric layer 220 may include a dielectric material including perovskite (ABO₃) or metal oxide (MOₓ). For example, the capacitor dielectric layer 220 may include SiO, TaO, tantalum aluminum oxide (TaAlO), tantalum oxynitride (TaON), AlO, aluminum silicon oxide (AlSiO), HfO, HfSiO, ZrO, ruthenium oxide (RuO), tungsten oxide (WO), hafnium zirconium oxide (HfZrO), ZrSiO, TiO, titanium aluminum oxide (TiAlO), vanadium oxide (VO), niobium oxide (NbO), molybdenum oxide (MoO), manganese oxide (MnO), lanthanum oxide (LaO), YO, cobalt oxide (CoO), nickel oxide (NiO), copper oxide (CuO), zinc oxide (ZnO), iron oxide (FeO), strontium oxide (SrO), barium oxide (BaO), barium strontium titanate ((Ba,Sr)TiO) (BST), strontium titanate (SrTiO) (STO), barium titanate (BaTiO) (BTO), lead titanate (PbTiO) (PTO), silver niobium oxide (AgNbO), bismuth iron oxide (BiFeO), lead zirconium titanate (Pb(Zr,Ti)O) (PZT), lead lanthanum zirconium titanate ((Pb,La)(Zr,Ti)O), barium zirconium titanate (Ba(Zr,Ti)O), strontium zirconium titanate (Sr(Zr,Ti)O), or a combination thereof. A configuration of the capacitor dielectric layer 220 is described in detail with reference to FIGS. 4A to 4C.

The upper electrode 230 may be formed as one body above the plurality of lower electrodes 210 in a certain region, e.g., one memory cell region CR (see FIG. 2). The plurality of lower electrodes 210, the capacitor dielectric layer 220, and the upper electrode 230 may form the plurality of capacitor structures 200 in a certain region, e.g., one memory cell region CR (see FIG. 2).

The upper electrode 230 may include impurity-doped silicon, a metal, e.g., W or copper, or a conductive metal compound, e.g., TiN. In some embodiments, the upper electrode 230 may include TiN, CrN, VN, MoN, NbN, TiSiN, TiAlN, or TaAlN. In some embodiments, the upper electrode 230 may have a stack structure including at least two of an impurity-doped semiconductor material layer, a main electrode layer, and an interface layer. The impurity-doped semiconductor material layer may include, e.g., doped polysilicon or doped polycrystalline SiGe. The main electrode layer may include a metal material. The main electrode layer may include, e.g., W, Ru, RuO, platinum (Pt), platinum oxide (PtO), iridium (Ir), iridium oxide (IrO), strontium ruthenium oxide (SrRuO) (SRO), barium strontium ruthenium oxide ((Ba,Sr)RuO) (BSRO), calcium ruthenium oxide (CaRuO) (CRO), barium ruthenium oxide (BaRuO), lanthanum strontium cobalt oxide (La(Sr,Co)O), or the like. In some embodiments, the main electrode layer may include W. The interface layer may include at least one of metal oxide, metal nitride, metal carbide, and metal silicide.

Each of FIGS. 4A to 4C is a cross-sectional view of a capacitor structure in a semiconductor memory device, according to embodiments. Particularly, FIG. 4A is an enlarged cross-sectional view of a part IV of FIG. 3A, and each of FIGS. 4B and 4C is an enlarged cross-sectional view of a part corresponding to the part IV of FIG. 3A.

Referring to FIGS. 3A and 4A, the semiconductor memory device 1 may include the plurality of capacitor structures 200 including the plurality of lower electrodes 210, the capacitor dielectric layer 220, and the upper electrode 230.

The capacitor dielectric layer 220 may have a stack structure including a lower interface layer 222, a dielectric structure 226, and an upper interface layer 228. The lower interface layer 222 may be between the dielectric structure 226 and the lower electrode 210, the upper interface layer 228 may be between the dielectric structure 226 and the upper electrode 230, and the dielectric structure 226 may be between the lower interface layer 222 and the upper interface layer 228. The dielectric structure 226 may include a material having an antiferroelectricity characteristic, a material having a ferroelectricity characteristic, or a material in which the antiferroelectricity characteristic is combined with the ferroelectricity characteristic.

The lower interface layer 222 may include a dielectric material doped with first conductive type impurities, and the upper interface layer 228 may include a dielectric material doped with second conductive type impurities other than the first conductive type impurities. In some embodiments, the first conductive type may be n type, and the second conductive type may be p type.

Each of the lower interface layer 222 and the upper interface layer 228 may include metal oxide. For example, the lower interface layer 222 may include tantalum pentoxide (Ta₂O₅), ruthenium pentoxide (Ru₂O₅), tungsten pentoxide (W₂O₅), niobium pentoxide (Nb₂O₅), molybdenum pentoxide (Mo₂O₅), manganese pentoxide (Mn₂O₅), or vanadium pentoxide (V₂O₅). For example, the upper interface layer 228 may include niobium trioxide (Nb₂O₃), Ta₂O₃, TiO, Al₂O₃, lanthanum trioxide (La₂O₃), Yttrium trioxide (Y₂O₃), CoO, NiO, CuO, ZnO, iron trioxide (Fe₂O₃), SrO, or BaO. In some embodiments, the first conductive type impurities may be metal atoms, which may cause a valence of the lower interface layer 222 to be greater than 4, and the second conductive type impurities may be metal atoms, which may cause a valence of the upper interface layer 228 to be less than 4. A percentage, i.e., the concentration, of the first conductive type impurities among metal atoms included in the lower interface layer 222 may be less than 5 atomic %. A percentage, i.e., the concentration, of the second conductive type impurities among metal atoms included in the upper interface layer 228 may be less than 5 atomic %. In some embodiments, the percentage of the first conductive type impurities among the metal atoms included in the lower interface layer 222 may be a little bit greater than the percentage of the second conductive type impurities among the metal atoms included in the upper interface layer 228.

When the lower interface layer 222 and the upper interface layer 228 include n-type impurities and p-type impurities, respectively, negative charges may be imparted to the lower interface layer 222, and positive charges may be imparted to the upper interface layer 228. Therefore, negative charges and positive charges are restrained in directions of the upper electrode 230 and the lower electrode 210, respectively, and thus, fixed polarization may be formed in the dielectric structure 226.

The dielectric structure 226 may include, e.g., SiO, TaO, TaAlO, TaON, AlO, AlSiO, HfO, HfSiO, ZrO, HfZrO, ZrSiO, TiO, TiAlO, VO, BST((Ba,Sr)TiO), STO(SrTiO), BTO(BaTiO), PTO(PbTiO), AgNbO, BiFeO, PZT(Pb(Zr,Ti)O), (Pb,La)(Zr,Ti)O, Ba(Zr,Ti)O, Sr(Zr,Ti)O, or a combination thereof.

In some embodiments, the dielectric structure 226 may have a stack structure including a lower dielectric layer 223, an upper dielectric layer 225, and an insertion layer 224 between the lower dielectric layer 223 and the upper dielectric layer 225. Each of the lower dielectric layer 223 and the upper dielectric layer 225 may include a material having an antiferroelectricity characteristic, a material having a ferroelectricity characteristic, or a material in which the antiferroelectricity characteristic is combined with the ferroelectricity characteristic. In some embodiments, the dielectric constant of the upper dielectric layer 225 may be greater than the dielectric constant of the lower dielectric layer 223. In some embodiments, a bandgap of the insertion layer 224 may be greater than each of a bandgap of the lower dielectric layer 223 and a bandgap of the upper dielectric layer 225. Because the insertion layer 224 has a relatively large bandgap, a leakage current occurring through the capacitor dielectric layer 220 may be reduced. For example, the insertion layer 224 may include Al₂O₃ or AlOₓ.

The capacitor dielectric layer 220 may have a first thickness T1. The first thickness T1 may be less than about 60 Å, e.g., about 30 Å to about 60 Å. The lower dielectric layer 223 may have a second thickness T2, and the upper dielectric layer 225 have a third thickness T3. A sum of the second thickness T2 and the third thickness T3 may be less than the first thickness T1. In some embodiments, the second thickness T2 and the third thickness T3 may have generally same values. For example, each of the second thickness T2 and the third thickness T3 may be greater than about 15 Å and less than about 30 Å.

The lower interface layer 222 may have a fourth thickness T4, and the upper interface layer 228 have a fifth thickness T5. In some embodiments, the fourth thickness T4 and the fifth thickness T5 may have generally same values. For example, each of the fourth thickness T4 and the fifth thickness T5 may be about 10 Å or less. In other some embodiments, the fourth thickness T4 may be greater than the fifth thickness T5. For example, the fourth thickness T4 may be about 10 Å or less, and the fifth thickness T5 may be about 7 Å or less. The insertion layer 224 may have a sixth thickness T6. In some embodiments, the sixth thickness T6 may be less than each of the fourth thickness T4 and the fifth thickness T5, e.g., the sixth thickness T6 may be about 5 Å or less.

Referring to FIGS. 3A and 4B, the semiconductor memory device 1 may include a capacitor structure 200a shown in FIG. 4B, instead of each of the plurality of capacitor structures 200 shown in FIGS. 3A and 4A. A plurality of capacitor structures 200a may include the plurality of lower electrodes 210, a capacitor dielectric layer 220a, and the upper electrode 230.

The capacitor dielectric layer 220a may have a stack structure including the lower interface layer 222, a dielectric structure 226a, and the upper interface layer 228. The lower interface layer 222 may be between the dielectric structure 226a and the lower electrode 210, the upper interface layer 228 may be between the dielectric structure 226a and the upper electrode 230, and the dielectric structure 226a may be between the lower interface layer 222 and the upper interface layer 228.

The lower interface layer 222 and the upper interface layer 228 are substantially the same as the lower interface layer 222 and the upper interface layer 228 described with reference to FIG. 4A. Thus, a detailed description thereof is omitted herein.

When the lower interface layer 222 and the upper interface layer 228 include n-type impurities and p-type impurities, respectively, negative charges may be imparted to the lower interface layer 222, and positive charges may be imparted to the upper interface layer 228. Therefore, negative charges and positive charges, which polarizations of the dielectric structure 226a have, are restrained in the directions of the upper electrode 230 and the lower electrode 210, respectively, and thus, fixed polarization may be formed in the dielectric structure 226a.

In some embodiments, the dielectric structure 226a may have a stack structure including a lower dielectric layer 223a, an upper dielectric layer 225a, and an insertion layer 224a between the lower dielectric layer 223a and the upper dielectric layer 225a. A material forming the dielectric structure 226a including the lower dielectric layer 223 a, the insertion layer 224a, and the upper dielectric layer 225a is substantially the same as the material forming the dielectric structure 226 including the lower dielectric layer 223, the insertion layer 224, and the upper dielectric layer 225 shown in FIG. 4A, and thus, a detailed description thereof is omitted herein. In some embodiments, the dielectric constant of the upper dielectric layer 225a may be greater than the dielectric constant of the lower dielectric layer 223a. In some embodiments, a bandgap of the insertion layer 224a may be greater than each of a bandgap of the lower dielectric layer 223a and a bandgap of the upper dielectric layer 225a. Because the insertion layer 224a has a relatively large bandgap, a leakage current occurring through the capacitor dielectric layer 220a may be reduced.

The capacitor dielectric layer 220a may have the first thickness T1. The first thickness T1 may be less than about 60 Å, e.g., about 30 Å to about 60 Å. The lower dielectric layer 223a may have a second thickness T2a, and the upper dielectric layer 225a have a third thickness T3a. A sum of the second thickness T2a and the third thickness T3a may be less than the first thickness T1. In some embodiments, the third thickness T3a may be greater than the second thickness T2a. For example, the second thickness T2a may be about 5 Å to about 15 Å, and the third thickness T3a may be about 25 Å to about 55 Å.

The lower interface layer 222 may have the fourth thickness T4, and the upper interface layer 228 may have the fifth thickness T5. The insertion layer 224a may have the sixth thickness T6. In some embodiments, the fourth thickness T4 may be greater than the fifth thickness T5. In some embodiments, the sixth thickness T6 may be less than each of the fourth thickness T4 and the fifth thickness T5.

Referring to FIGS. 3A and 4C, the semiconductor memory device 1 may include a capacitor structure 200b shown in FIG. 4C, instead of each of the plurality of capacitor structures 200 shown in FIGS. 3A and 4A. A plurality of capacitor structures 200b may include the plurality of lower electrodes 210, a capacitor dielectric layer 220b, and the upper electrode 230.

The capacitor dielectric layer 220b may have a stack structure including the lower interface layer 222, a dielectric structure 226b, and the upper interface layer 228. The lower interface layer 222 may be between the dielectric structure 226b and the lower electrode 210, the upper interface layer 228 may be between the dielectric structure 226b and the upper electrode 230, and the dielectric structure 226b may be between the lower interface layer 222 and the upper interface layer 228.

The lower interface layer 222 and the upper interface layer 228 are substantially the same as the lower interface layer 222 and the upper interface layer 228 described with reference to FIG. 4A. Thus, a detailed description thereof is omitted herein.

When the lower interface layer 222 and the upper interface layer 228 include n-type impurities and p-type impurities, respectively, negative charges may be imparted to the lower interface layer 222, and positive charges may be imparted to the upper interface layer 228. Therefore, negative charges and positive charges, which polarizations of the dielectric structure 226b have, are restrained in the directions of the upper electrode 230 and the lower electrode 210, respectively, and thus, fixed polarization may be formed in the dielectric structure 226b.

In some embodiments, the dielectric structure 226b may include SiO, TaO, TaAlO, TaON, AlO, AlSiO, HfO, HfSiO, ZrO, HfZrO, ZrSiO, TiO, TiAlO, VO, BST((Ba,Sr)TiO), STO(SrTiO), BTO(BaTiO), PTO(PbTiO), AgNbO, BiFeO, PZT(Pb(Zr,Ti)O), (Pb,La)(Zr,Ti)O, Ba(Zr,Ti)O, Sr(Zr,Ti)O, or a combination thereof. The dielectric structure 226b may not include the insertion layer 224 included in the dielectric structure 226 shown in FIG. 4A or the insertion layer 224a included in the dielectric structure 226a shown in FIG. 4B.

The capacitor dielectric layer 220b may have the first thickness T1. The first thickness T1 may be less than about 60 Å, e.g., about 30 Å to about 60 Å. The dielectric structure 226b may have a second thickness T2b. The second thickness T2b may be less than the first thickness T1. The lower interface layer 222 may have the fourth thickness T4, and the upper interface layer 228 have the fifth thickness T5. In some embodiments, the fourth thickness T4 may be greater than the fifth thickness T5.

Referring to FIGS. 3A to 4C, the capacitor dielectric layer 220, 220a, or 220b included in the semiconductor memory device 1 has fixed polarization formed by the lower interface layer 222 and the upper interface layer 228, and thus, a capacitance of the capacitor structure 200, 200a, or 200b may increase. Therefore, the semiconductor memory device 1 may ensure the capacity of a capacitor.

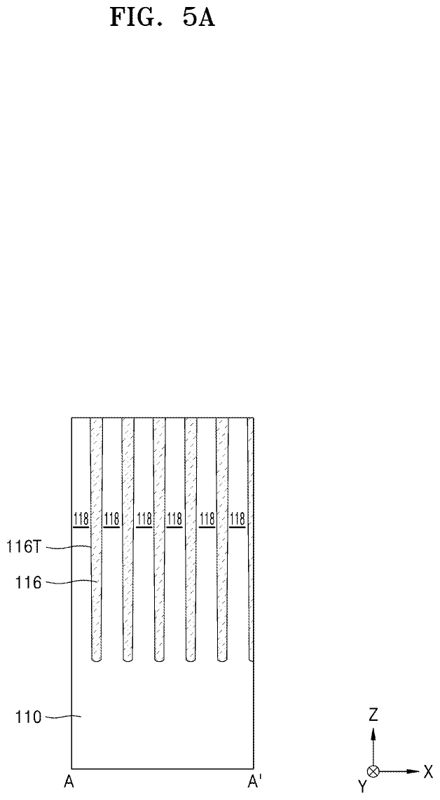

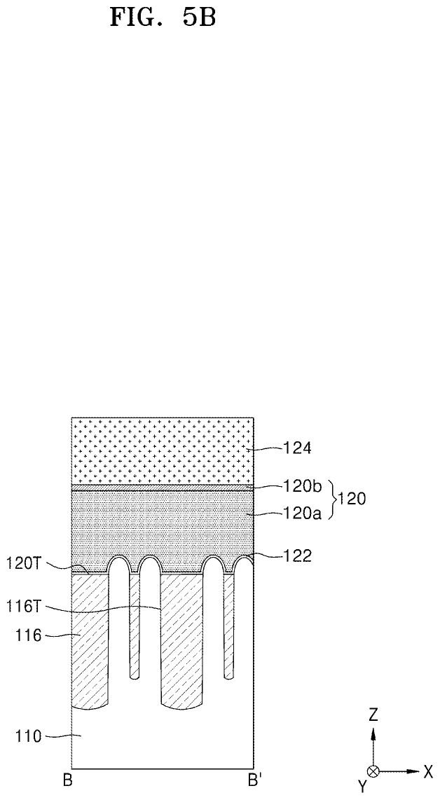

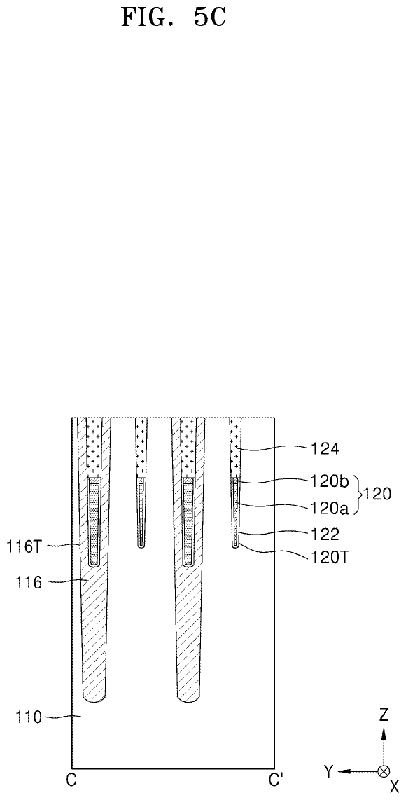

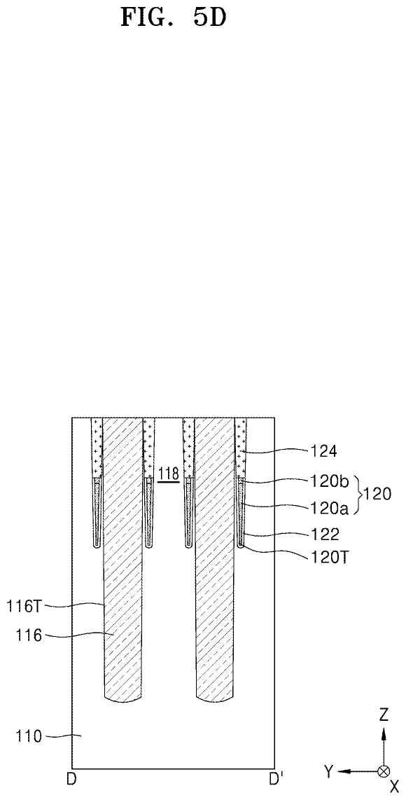

FIGS. 5A to 5D, 6A to 6D, 7A to 7D, 8A to 8D, and 9A to 9D are cross-sectional views illustrating stages in a method of manufacturing a semiconductor memory device, according to embodiments. Particularly, FIGS. 5A, 6A, 7A, 8A, and 9A are cross-sectional views taken along line A-A′ of FIG. 2, FIGS. 5B, 6B, 7B, 8B, and 9B are cross-sectional views taken along line B-B′ of FIG. 2, FIGS. 5C, 6C, 7C, 8C, and 9C are cross-sectional views taken along line C-C′ of FIG. 2, and FIGS. 5D, 6D, 7D, 8D, and 9D are cross-sectional views taken along line D-D′ of FIG. 2.

Referring to FIGS. 5A to 5D, the plurality of active regions 118 limited by the device isolation trench 116T are formed by removing a portion of the substrate 110. The plurality of active regions 118 may be formed to have a relatively long island shape having a short axis and a long axis in a top view. In some embodiments, the plurality of active regions 118 may be formed to have the long axis in a diagonal direction with respect to the first horizontal direction and the second horizontal direction.

The device isolation layer 116 filling the device isolation trench 116T is formed. The plurality of active regions 118 may be defined in the substrate 110 by the device isolation layer 116. In some embodiments, the device isolation layer 116 may be formed to include a triple layer including a first device isolation layer, a second device isolation layer, and a third device isolation layer. For example, the first device isolation layer may be formed to conformally cover the inner side surface and the bottom surface of the device isolation trench 116T. In some embodiments, the first device isolation layer may include SiO. For example, the second device isolation layer may be formed to conformally cover the first device isolation layer. In some embodiments, the second device isolation layer may include SiN. For example, the third device isolation layer may be formed to cover the second device isolation layer and fill the device isolation trench 116T. In some embodiments, the third device isolation layer may include SiO. For example, the third device isolation layer may include SiO including TOSZ. In some embodiments, the device isolation layer 116 may be formed by a single layer including one type of insulating layer, a double layer including two types of insulating layers, or a multi-layer including a combination of at least four types of insulating layers. For example, the device isolation layer 116 may be formed by a single layer including SiO.

The plurality of word line trenches 120T may be formed in the substrate 110 including the plurality of active regions 118 defined by the device isolation layer 116. The plurality of word line trenches 120T may be formed to have line shapes extending in the first horizontal direction (the X direction) to be parallel to each other, and arranged to have generally equal intervals in the second horizontal direction (the Y direction) with each word line trench 120T crossing the active region 118. In some embodiments, stepped portions may be formed on the bottom surfaces of the plurality of word line trenches 120T, respectively.

After cleaning a result formed with the plurality of word line trenches 120T, the plurality of gate dielectric layers 122, the plurality of word lines 120, and the plurality of buried insulating layers 124 may be sequentially formed inside the plurality of word line trenches 120T, respectively. The plurality of word lines 120 may have line shapes extending in the first horizontal direction (the X direction) to be parallel to each other, and arranged to have generally equal intervals in the second horizontal direction (the Y direction) with each word line 120 crossing the active region 118. The upper surface of each of the plurality of word lines 120 may be formed to be at a vertical level that is lower than the upper surface of the substrate 110. The lower surfaces of the plurality of word lines 120 may have a concave-convex shape corresponding to the stepped portions formed on the bottom surfaces of the plurality of word line trenches 120T. Saddle Fin FETs may be respectively formed in the plurality of active regions 118.

The gate dielectric layer 122 may be formed to cover the inner side wall and the bottom surface of the word line trench 120T. In some embodiments, the gate dielectric layer 122 may be formed to extend from between the word line 120 and the word line trench 120T to between the buried insulating layer 124 and the word line trench 120T. The gate dielectric layer 122 may include at least one of SiO, SiN, silicon oxynitride, ONO, and a high-k dielectric material having a higher dielectric constant than SiO. For example, the gate dielectric layer 122 may have a dielectric constant of about 10 to about 25. In some embodiments, the gate dielectric layer 122 includes at least one of HfO, HfSiO, HfON, HfSiON, LaO, LaAlO, ZrO, ZrSiO, ZrON, ZrSiON, TaO, TiO, BaSrTiO, BaTiO, SrTiO, YO, AlO, and PbScTaO. For example, the gate dielectric layer 122 may include HfO₂, Al₂O₃, HfAlO₃, Ta₂O₃, or TiO₂.

The plurality of word lines 120 may be formed to fill the lower portions of the plurality of word line trenches 120T, respectively. Each of the plurality of word lines 120 may be formed to have a stack structure including the lower word line layer 120a and the upper word line layer 120b. For example, the lower word line layer 120a may be formed to conformally cover the inner side wall and the bottom surface of the lower portion of the word line trench 120T with the gate dielectric layer 122 therebetween. For example, the upper word line layer 120b may be formed to cover the lower word line layer 120a and fill the lower portion of the word line trench 120T. In some embodiments, the lower word line layer 120a may include a metal material or a conductive metal nitride, e.g., Ti, TiN, Ta, or TaN. For example, the upper word line layer 120b may include doped polysilicon, a metal material, e.g., W, a conductive metal nitride, e.g., WN, TiSiN, or WSiN, or a combination thereof.

In some embodiments, before or after forming the plurality of word lines 120, source regions and drain regions may be formed in the plurality of active regions 118 by injecting impurity ions into portions of the plurality of active regions 118 of the substrate 110 at both sides of the plurality of word lines 120, respectively.

The plurality of buried insulating layers 124 may be formed to fill the upper portions of the plurality of word line trenches 120T, respectively. The plurality of buried insulating layers 124 may be formed so that the upper surfaces of the plurality of buried insulating layers 124 are at substantially the same vertical level as the upper surface of the substrate 110. The buried insulating layer 124 may include at least one of SiO, SiN, silicon oxynitride, and a combination thereof. For example, the buried insulating layer 124 may include SiN.

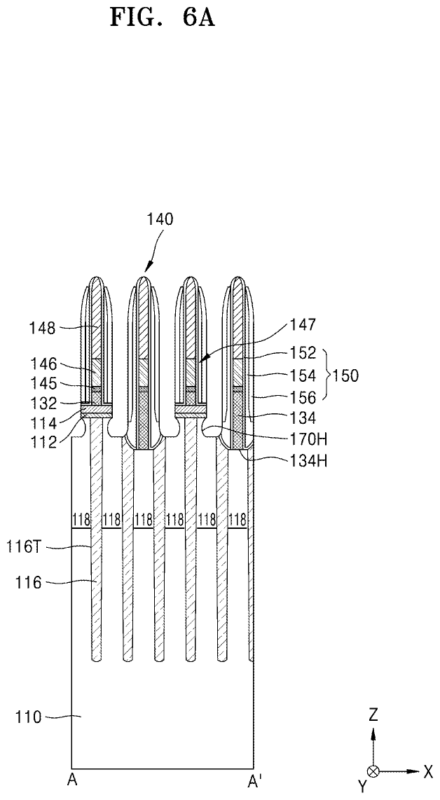

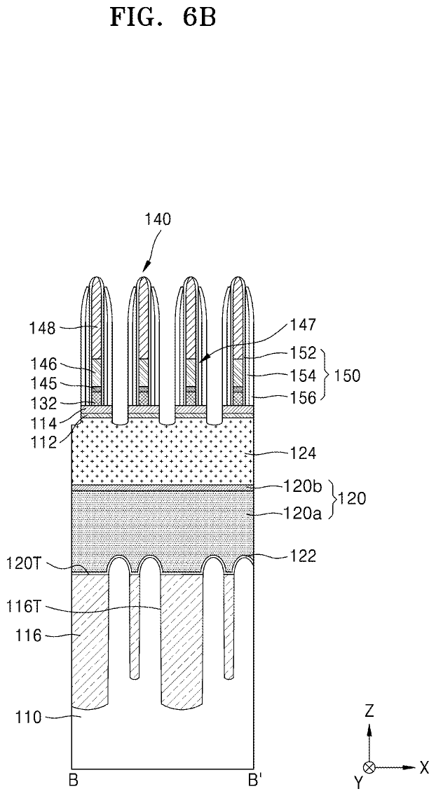

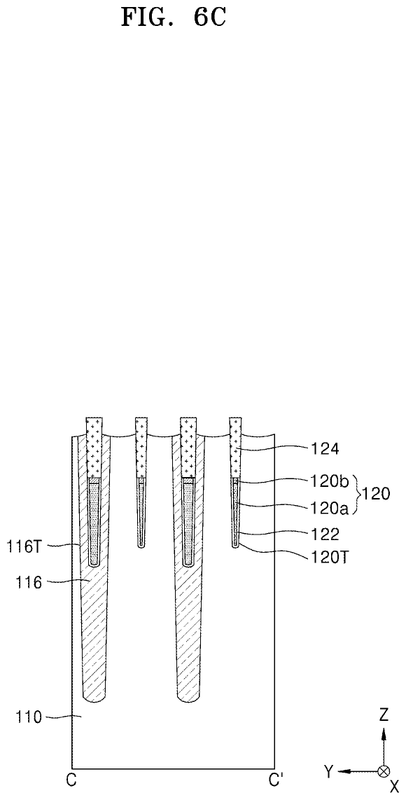

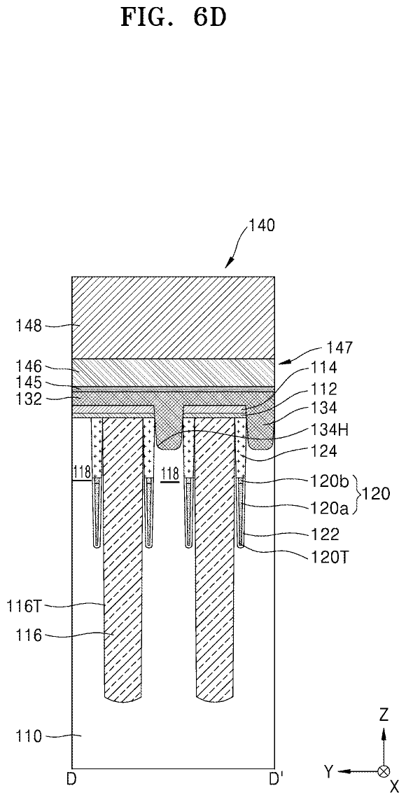

Referring to FIGS. 6A to 6D, the insulating layer patterns covering the device isolation layer 116 and the plurality of active regions 118 are formed. For example, the insulating layer patterns may include SiO, SiN, silicon oxynitride, a metal-based dielectric material, or a combination thereof. In some embodiments, the insulating layer patterns may be formed to have a stack structure of the first insulating layer pattern 112 and the second insulating layer pattern 114 on the first insulating layer pattern 112. In some embodiments, the first insulating layer pattern 112 may include SiO, and the second insulating layer pattern 114 may include silicon oxynitride. In other some embodiments, the first insulating layer pattern 112 may include a non-metal-based dielectric material, and the second insulating layer pattern 114 may include a metal-based dielectric material. In some embodiments, the second insulating layer pattern 114 may be formed to be thicker than the first insulating layer pattern 112. For example, the first insulating layer pattern 112 may be formed to have a thickness of about 50 Å to about 90 Å, and the second insulating layer pattern 114 may be formed to be thicker than the first insulating layer pattern 112 and have a thickness of about 60 Å to about 100 Å.

Thereafter, after forming a conductive semiconductor layer on the insulating layer patterns, the direct contact hole 134H, which exposes the source region of the active region 118 by passing through the conductive semiconductor layer and the insulating layer patterns, is formed, and a direct contact conductive layer filling the direct contact hole 134H is formed. In some embodiments, the direct contact hole 134H may extend to the inside of the active region 118, i.e., the inside of the source region. The conductive semiconductor layer may include, e.g., doped polysilicon. The direct contact conductive layer may include, e.g., doped polysilicon. In some embodiments, the direct contact conductive layer may include an epitaxial silicon layer.

A metal-based conductive layer and an insulating capping layer for forming the bit line structure 140 are sequentially formed on the conductive semiconductor layer and the direct contact conductive layer. In some embodiments, the metal-based conductive layer may have a stack structure including a first metal-based conductive layer and a second metal-based conductive layer. The plurality of bit lines 147 having a stack structure of the first metal-based conductive pattern 145 and the second metal-based conductive pattern 146, and the plurality of insulating capping lines 148 are formed in line shapes by etching the first metal-based conductive layer, the second metal-based conductive layer, and the insulating capping layer.

In some embodiments, the first metal-based conductive pattern 145 may include TiN or TSN, and the second metal-based conductive pattern 146 may include W or W and WSiₓ. In some embodiments, the first metal-based conductive pattern 145 may function as a diffusion barrier. In some embodiments, the plurality of insulating capping lines 148 may include SiN.

One bit line 147 and one insulating capping line 148 covering the one bit line 147 may form one bit line structure 140. The plurality of bit line structures 140, each including the bit line 147 and the insulating capping line 148 covering the bit line 147, may extend in parallel to each other in the second horizontal direction (the Y direction), which is parallel to the main surface of the substrate 110. The plurality of bit lines 147 may respectively form the plurality of bit lines BL shown in FIG. 2. In some embodiments, the bit line structure 140 may further include the conductive semiconductor pattern 132, which is a portion of the conductive semiconductor layer, between the insulating layer patterns and the first metal-based conductive pattern 145.

In an etching process of forming the plurality of bit lines 147, a plurality of conductive semiconductor patterns 132 and the plurality of direct contact conductive patterns 134 may be formed by removing both a portion of the conductive semiconductor layer and a portion of the direct contact conductive layer, which do not vertically overlap the bit line 147, in the etching process. In this case, the insulating layer patterns may function as an etching stop layer in the etching process of forming the plurality of bit lines 147, the plurality of conductive semiconductor patterns 132, and the plurality of direct contact conductive patterns 134. The plurality of bit lines 147 may be formed to be electrically connected to the plurality of active regions 118 via the plurality of direct contact conductive patterns 134, respectively.

The insulating spacer structure 150 covering both side walls of each of the plurality of bit line structures 140 may be formed. Each of the plurality of insulating spacer structures 150 may be formed to include the first insulating spacer 152, the second insulating spacer 154, and the third insulating spacer 156. The second insulating spacer 154 may include a material having a lower dielectric constant than a dielectric constant of the first insulating spacer 152 and a dielectric constant of the third insulating spacer 156. In some embodiments, the first insulating spacer 152 and the third insulating spacer 156 may include nitride, and the second insulating spacer 154 may include oxide. In some embodiments, the first insulating spacer 152 and the third insulating spacer 156 may include nitride, and the second insulating spacer 154 may include a material having an etching selectivity with respect to the first insulating spacer 152 and the third insulating spacer 156. For example, when the first insulating spacer 152 and the third insulating spacer 156 include nitride, the second insulating spacer 154 may include oxide and become an air spacer by being removed in a subsequent process. In some embodiments, the insulating spacer structure 150 may include the second insulating spacer 154 including oxide and the third insulating spacer 156 including nitride.

The plurality of insulating fences 180 are formed in spaces between the plurality of insulating spacer structures 150 covering both side walls of the plurality of bit line structures 140, respectively. The plurality of insulating fences 180 may be separated from each other and arranged in lines between every pair of insulating spacer structures 150 facing each other among the plurality of insulating spacer structures 150 covering both side walls of the plurality of bit line structures 140, i.e., in the second horizontal direction (the Y direction). For example, the plurality of insulating fences 180 may include nitride.

In some embodiments, the plurality of insulating fences 180 may be formed to extend to the inside of the buried insulating layer 124 by passing through the insulating layer patterns. In other some embodiments, the plurality of insulating fences 180 may be formed to pass through the insulating layer patterns but not to extend to the inside of the buried insulating layer 124, to extend to the inside of the buried insulating layer 124 but not to pass through the insulating layer patterns, or not to extend to the inside of the buried insulating layer 124 so that the lower surfaces of the plurality of insulating fences 180 are in contact with the insulating layer patterns.

Between every two of the plurality of bit lines 147, the plurality of buried contact holes 170H may be formed between the plurality of insulating fences 180, respectively. The plurality of buried contact holes 170H and the plurality of insulating fences 180 may be alternately arranged between every pair of insulating spacer structures 150 facing each other among the plurality of insulating spacer structures 150 covering both side walls of the plurality of bit line structures 140, i.e., in the second horizontal direction. Each of the plurality of buried contact holes 170H may have an internal space limited by the insulating fence 180, the active region 118, and the insulating spacer structure 150 covering a side wall of each of two neighboring bit lines 147 between the two neighboring bit lines 147 among the plurality of bit lines 147.

The plurality of buried contact holes 170H may be formed by removing portions of the insulating layer patterns and the plurality of active regions 118 by using, as an etching mask, the plurality of insulating capping lines 148, the insulating spacer structure 150 covering both side walls of each of the plurality of bit line structures 140, and the plurality of insulating fences 180. In some embodiments, the plurality of buried contact holes 170H may be formed by first performing an anisotropic etching process of removing portions of the insulating layer patterns and the plurality of active regions 118 by using, as an etching mask, the plurality of insulating capping lines 148, the insulating spacer structure 150 covering both side walls of each of the plurality of bit line structures 140, and the plurality of insulating fences 180, and then performing an isotropic etching process of further removing other portions of the plurality of active regions 118 to expand spaces limited by the plurality of active regions 118.

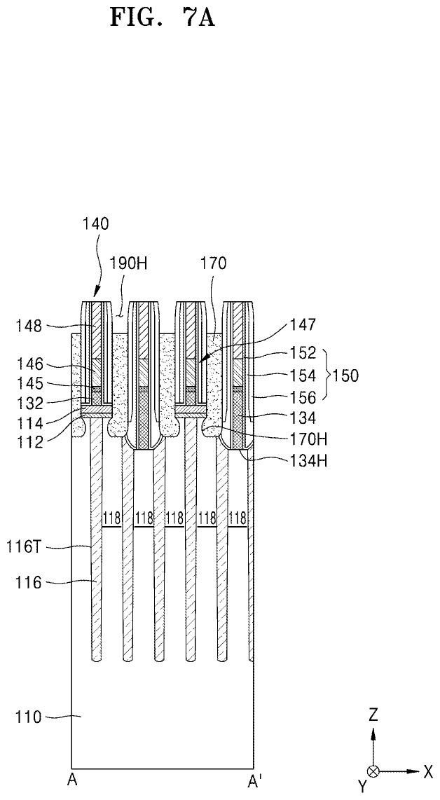

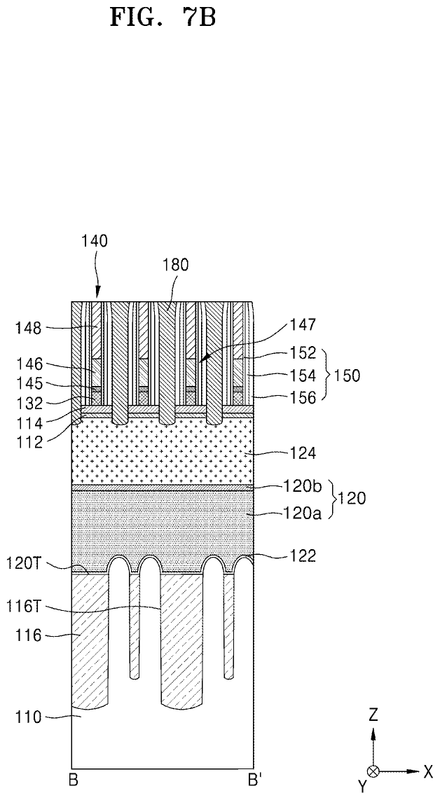

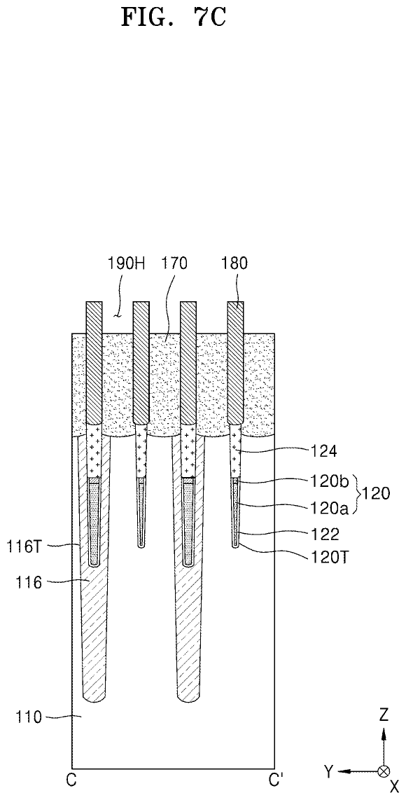

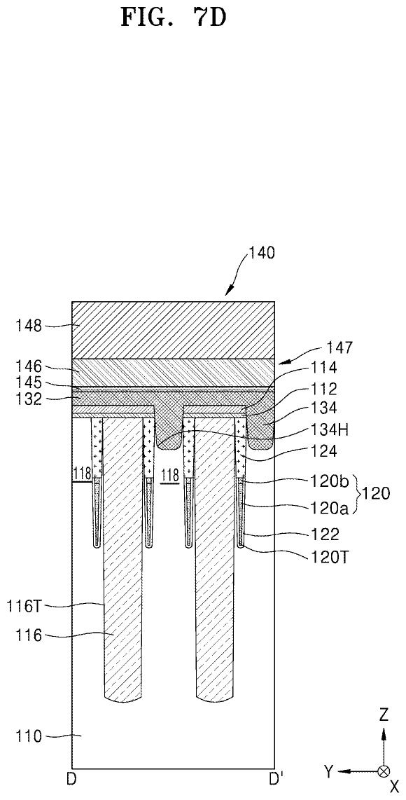

Referring to FIGS. 7A to 7D, the plurality of buried contacts 170 are formed in the plurality of buried contact holes 170H. The plurality of buried contacts 170 and the plurality of insulating fences 180 may be alternately arranged between every pair of insulating spacer structures 150 facing each other among the plurality of insulating spacer structures 150 covering both side walls of the plurality of bit line structures 140, i.e., in the second horizontal direction (the Y direction). For example, the plurality of buried contacts 170 may include polysilicon.

In some embodiments, the plurality of buried contacts 170 may be arranged in lines in each of the first horizontal direction (the X direction) and the second horizontal direction (the Y direction). Each of the plurality of buried contacts 170 may extend from the active region 118 in the vertical direction (the z direction) that is perpendicular to the substrate 110. The plurality of buried contacts 170 may form the plurality of buried contacts BC shown in FIG. 2.

The plurality of buried contacts 170 may be in the plurality of buried contact holes 170H, which are spaces limited by the plurality of insulating fences 180 and the plurality of insulating spacer structures 150 covering both side walls of the plurality of bit line structures 140, respectively. The plurality of buried contacts 170 may respectively fill lower portions of spaces between the plurality of insulating fences 180 and the plurality of insulating spacer structures 150 covering both side walls of the plurality of bit line structures 140.

The levels of the upper surfaces of the plurality of buried contacts 170 may be lower than the levels of the upper surfaces of the plurality of insulating capping lines 148. The upper surfaces of the plurality of insulating fences 180 and the upper surfaces of the plurality of insulating capping lines 148 may be at the same vertical level in the vertical direction (the z direction).

The plurality of landing pad holes 190H may be limited by the plurality of buried contacts 170, the plurality of insulating spacer structures 150, and the plurality of insulating fences 180, respectively. The plurality of buried contacts 170 may be exposed at the bottom surfaces of the plurality of landing pad holes 190H.

In a process of forming the plurality of buried contacts 170, upper portions of the insulating capping line 148 and the insulating spacer structure 150 included in the bit line structure 140 may be removed, thereby lowering a level of an upper surface of the bit line structure 140.

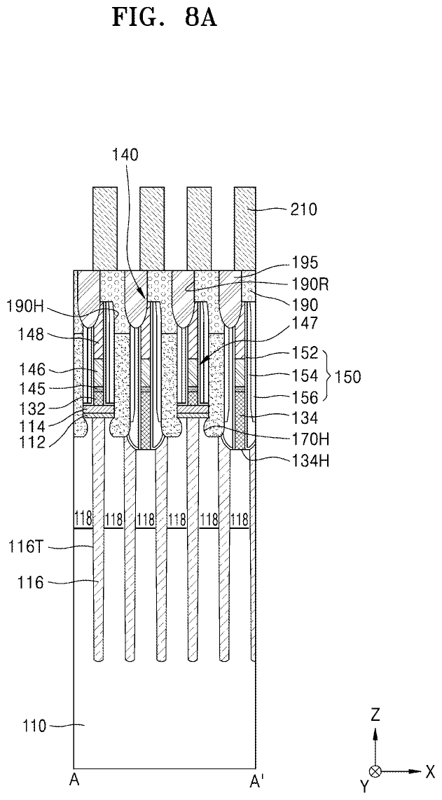

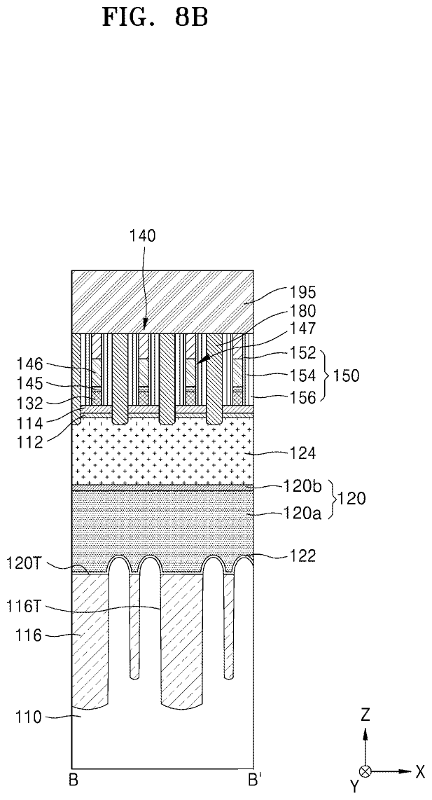

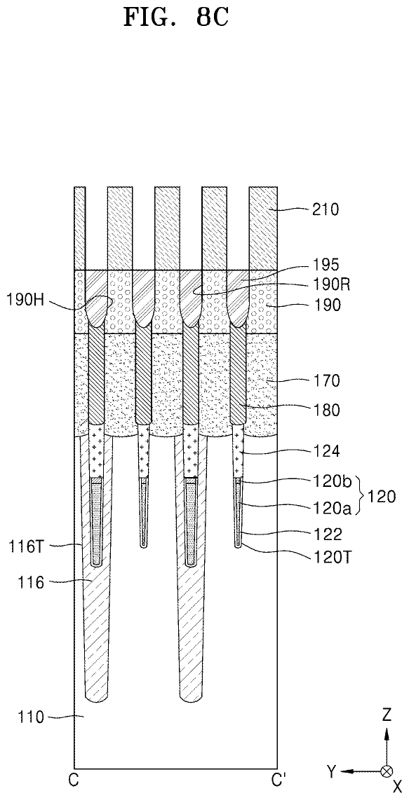

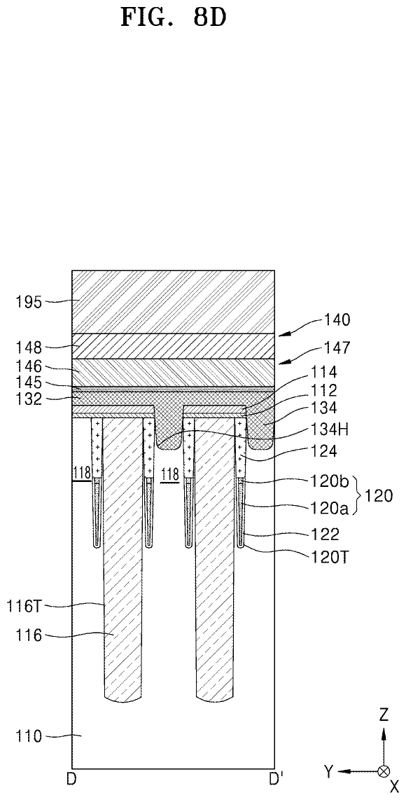

Referring to FIGS. 8A to 8D, the recess parts 190R may be formed by forming a landing pad material layer filling the plurality of landing pad holes 190H and covering the plurality of bit line structures 140, and then removing a portion of the landing pad material layer. The plurality of landing pads 190 separated by the recess parts 190R may be formed. The plurality of landing pads 190 may fill at least portions of the plurality of landing pad holes 190H and extend above the plurality of bit line structures 140.

In some embodiments, the landing pad material layer may include a conductive barrier layer and a conductive pad material layer on the conductive barrier layer. For example, the conductive barrier layer may include a metal, conductive metal nitride, or a combination thereof. In some embodiments, the conductive barrier layer may have a stack structure including Ti/TiN. In some embodiments, the conductive pad material layer may include W.

In some embodiments, before forming the landing pad material layer, a metal silicide layer may be formed on the plurality of buried contacts 170. The metal silicide layer may be between the plurality of buried contacts 170 and the landing pad material layer. The metal silicide layer may include CoSiₓ, NiSiₓ, or MnSiₓ.

The plurality of landing pads 190 may be separated from each other with the recess part 190R therebetween. The plurality of landing pads 190 may be on the plurality of buried contacts 170 and extend above the plurality of bit line structures 140. In some embodiments, the plurality of landing pads 190 may extend above the plurality of bit lines 147. The plurality of landing pads 190 may be on the plurality of buried contacts 170 and electrically connected to the plurality of buried contacts 170, respectively. The plurality of landing pads 190 may be connected to the plurality of active regions 118 via the plurality of buried contacts 170, respectively.

The recess parts 190R may be filled with the insulating structure 195. In some embodiments, the insulating structure 195 may include an interlayer insulating layer and an etching stop layer. For example, the interlayer insulating layer may include oxide, and the etching stop layer may include nitride. For example, as illustrated in FIGS. 8A and 8C, the upper surface of the insulating structure 195 and the upper surfaces of the plurality of landing pads 190 may be at the same vertical level. In another example, the insulating structure 195 may have an upper surface at a higher vertical level than the upper surfaces of the plurality of landing pads 190 by filling the recess parts 190R and covering the upper surfaces of the plurality of landing pads 190.

The plurality of lower electrodes 210 are formed on the plurality of landing pads 190. In some embodiments, the plurality of lower electrodes 210 may be formed by performing a deposition process under a temperature condition of about 450° C. to about 700° C. The plurality of lower electrodes 210 may be electrically connected to the plurality of landing pads 190, respectively. For example, as illustrated in FIGS. 8A and 8C, the upper surface of the insulating structure 195 and the lower surface of the lower electrode 210 are at the same vertical level.

Each of the plurality of lower electrodes 210 may be formed to have a pillar shape with the inside filled to have a circular horizontal cross-section. In some embodiments, each of the plurality of lower electrodes 210 may be formed to have a cylindrical shape with a closed bottom. In some embodiments, the plurality of lower electrodes 210 may be in a honeycomb shape arranged zigzag in the first horizontal direction (the X direction) or the second horizontal direction (the Y direction). In other some embodiments, the plurality of plurality of lower electrodes 210 may be in a matrix shape arranged in lines in each of the first horizontal direction (the X direction) and the second horizontal direction (the Y direction). The plurality of lower electrodes 210 may include, e.g., impurity-doped silicon, a metal, e.g., W or copper, or a conductive metal compound, e.g., TiN. Although not shown, at least one support pattern in contact with the side walls of the plurality of lower electrodes 210 may be further formed.

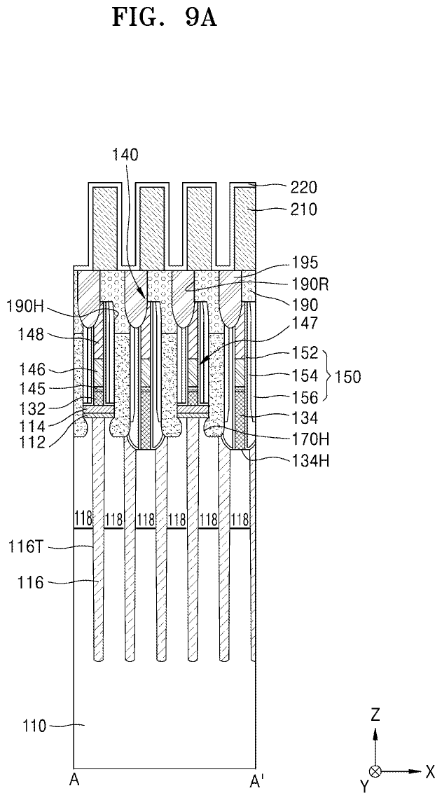

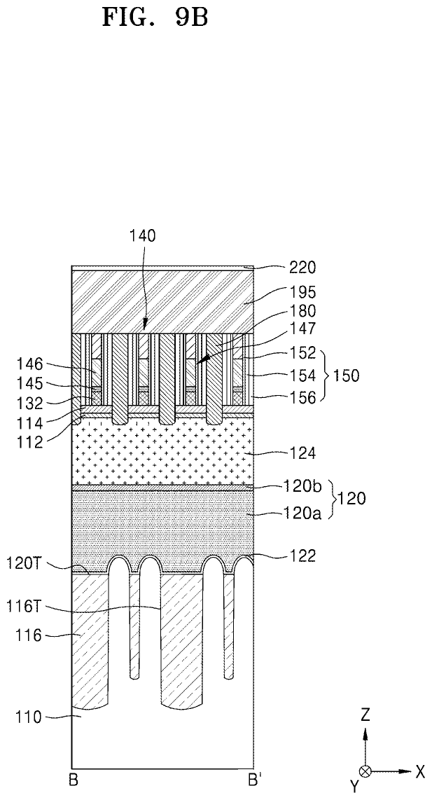

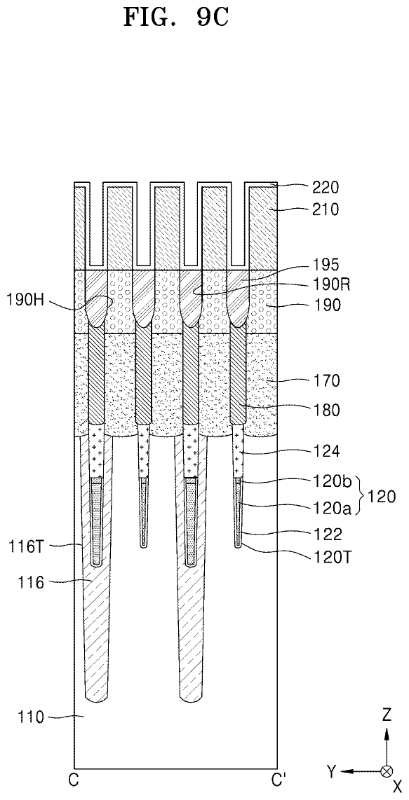

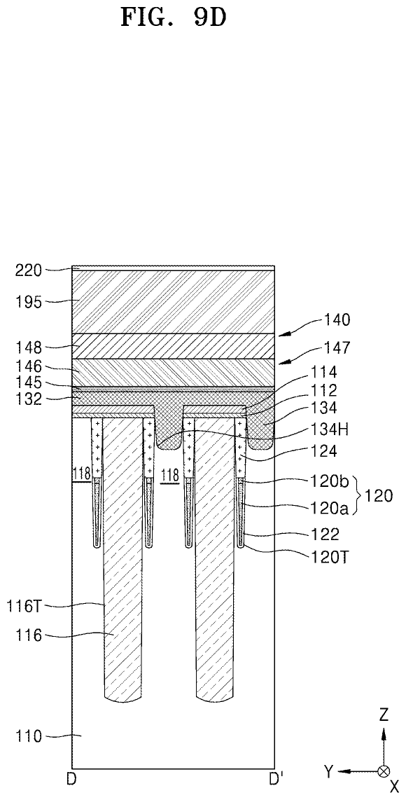

Referring to FIGS. 9A to 9C, the capacitor dielectric layer 220 covering the plurality of lower electrodes 210 is formed. The capacitor dielectric layer 220 may be formed to conformally cover the surfaces of the plurality of lower electrodes 210. In some embodiments, the capacitor dielectric layer 220 may be formed as one body to conformally cover the surfaces of the plurality of lower electrodes 210 in a certain region, e.g., one memory cell region CR (see FIG. 2). The capacitor dielectric layer 220 may be formed by performing a deposition process under a temperature condition of about 400° C. or less. In some embodiments, to form the capacitor dielectric layer 220, an annealing process under a temperature condition of about 200° C. to about 700° C. may be performed. The capacitor dielectric layer 220 may be formed to have a stack structure including the lower interface layer 222, the dielectric structure 226, and the upper interface layer 228, like the capacitor dielectric layer 220 shown in FIG. 4A. In some embodiments, the lower interface layer 222, the dielectric structure 226, and the upper interface layer 228 may be formed in situ. Alternatively, instead of the capacitor dielectric layer 220, the capacitor dielectric layer 220a shown in FIG. 4B or the capacitor dielectric layer 220b shown in FIG. 4C may be formed. The lower interface layer 222, the dielectric structure 226a, and the upper interface layer 228 forming the capacitor dielectric layer 220a shown in FIG. 4B may be formed in situ. The lower interface layer 222, the dielectric structure 226b, and the upper interface layer 228 forming the capacitor dielectric layer 220b shown in FIG. 4C may be formed in situ.

Thereafter, as shown in FIGS. 3A to 3D, the upper electrode 230 covering the capacitor dielectric layer 220 may be formed to form the plurality of capacitor structures 200 including the plurality of lower electrodes 210, the capacitor dielectric layer 220, and the upper electrode 230.

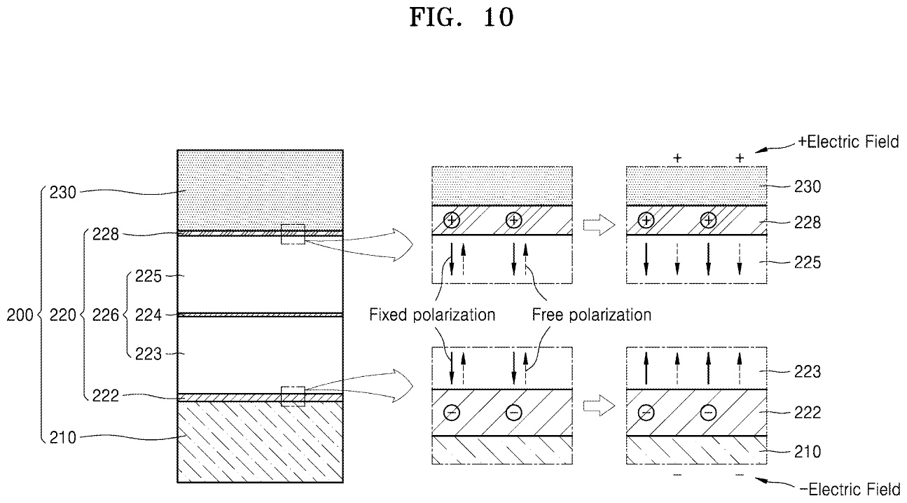

FIG. 10 is a conceptual diagram of describing an operation of a semiconductor memory device according to embodiments.

Referring to FIG. 10, the capacitor structure 200 included in the semiconductor memory device 1 shown in FIGS. 3A to 3D may have a stack structure including the lower interface layer 222, the dielectric structure 226, and the upper interface layer 228. In some embodiments, the dielectric structure 226 may have a stack structure including the lower dielectric layer 223, the upper dielectric layer 225, and the insertion layer 224 between the lower dielectric layer 223 and the upper dielectric layer 225. In other some embodiments, the insertion layer 224 may be omitted.

When the lower interface layer 222 and the upper interface layer 228 include n-type impurities and p-type impurities, respectively, negative charges may be imparted to the lower interface layer 222, and positive charges may be imparted to the upper interface layer 228. Therefore, negative charges and positive charges, which polarizations of the dielectric structure 226 have, are restrained in directions of the upper electrode 230 and the lower electrode 210, respectively, and thus, fixed polarization may be formed in the dielectric structure 226. Polarizations of which directions are not restrained by the negative charges imparted to the lower interface layer 222 and the positive charges imparted to the upper interface layer 228 among the polarizations of the dielectric structure 226 may be referred to as free polarizations.

When applying a positive electric field to the upper electrode 230 and applying a negative electric field to the lower electrode 210, negative charges, which the free polarizations of the dielectric structure 226 have, are restrained in a direction of the upper electrode 230, and positive charges, which the free polarizations of the dielectric structure 226 have, are restrained in a direction of the lower electrode 210. Therefore, in the capacitor dielectric layer 220, the fixed polarizations and the free polarizations are restrained in the same direction, and thus, a capacitance of the capacitor structure 200 may increase.

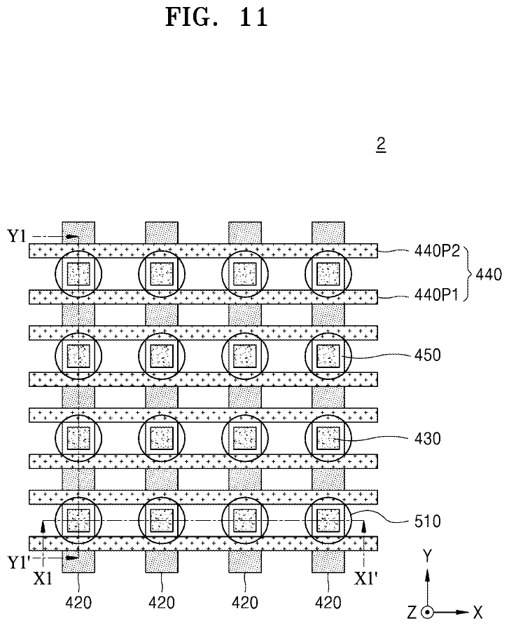

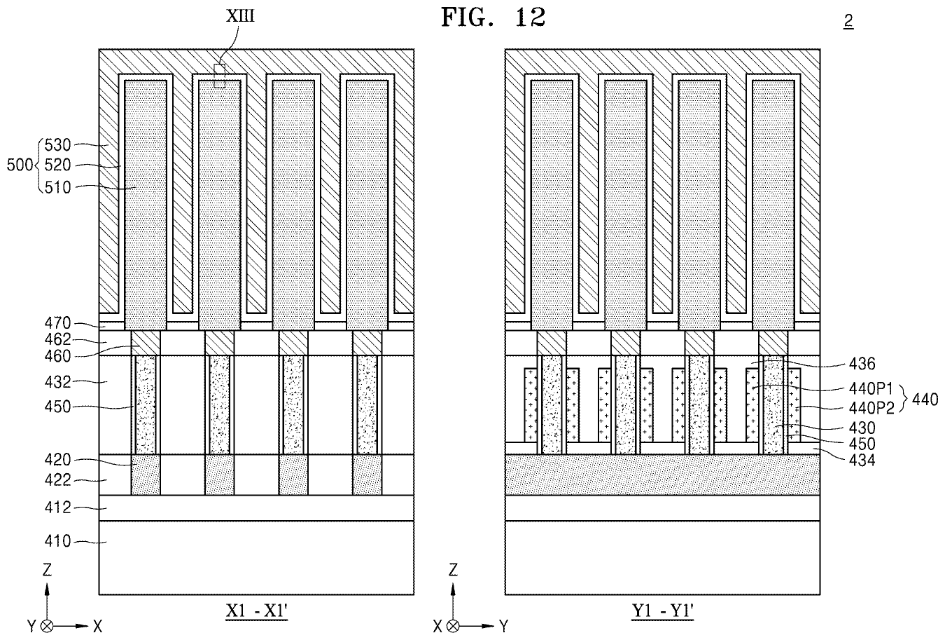

FIG. 11 is a layout diagram illustrating a semiconductor memory device 2 according to embodiments. FIG. 12 is a cross-sectional view along line X1-X1′ and line Y1-Y1′ of FIG. 11.

Referring to FIGS. 11 and 12, the semiconductor memory device 2 may include a substrate 410, a plurality of first conductive lines 420, a plurality of channel layers 430, a plurality of gate electrodes 440, a plurality of gate insulating layers 450, and a plurality of capacitor structures 500. An integrated circuit (IC) device 400 may be a memory device including a vertical channel transistor (VCT). The VCT may refer to a structure in which the plurality of channel layers 430 extend from the substrate 410 in a vertical direction.

A lower insulating layer 412 may be arranged on the substrate 410 and the plurality of first conductive lines 420 may be spaced apart from one another on the lower insulating layer 412 in the first horizontal direction (the X direction) and may extend in the second horizontal direction (the Y direction). A plurality of first insulating patterns 422 may be arranged on the lower insulating layer 412 to fill spaces among the plurality of first conductive lines 420. The plurality of first insulating patterns 422 may extend in the second horizontal direction (the Y direction) and the upper surface of each of the plurality of first insulating patterns 422 may be at the same level as an upper surface of each of the plurality of first conductive lines 420. The plurality of first conductive lines 420 may function as a plurality of bit lines of the semiconductor memory device 2.

For example, each of the plurality of first conductive lines 420 may include doped polysilicon, a metal, conductive metal nitride, conductive metal silicide, conductive metal oxide, or a combination of the above materials. For example, each of the first conductive lines 420 may include doped polysilicon, Al, Cu, Ti, Ta, ruthenium (Ru), W, molybdenum (Mo), platinum (Pt), nickel (Ni), cobalt (Co), TiN, TaN, WN, NbN, TiAl, TiAlN, TiSi, TiSiN, TaSi, TaSiN, RuTiN, NiSi, CoSi, IrOx, RuOx, or a combination of the above materials. Each of the first conductive lines 420 may include a single layer or a multilayer of the above materials. In example embodiments, the plurality of first conductive lines 420 may include a two-dimensional semiconductor material, e.g., graphene, carbon nanotube, or a combination of the above materials.

The plurality of channel layers 430 may be arranged in a matrix on the plurality of first conductive lines 420 to be spaced apart from one another in the first horizontal direction (the X direction) and the second horizontal direction (the Y direction). Each of the plurality of channel layers 430 may have a first width in the first horizontal direction and a first height in a third direction (the Z direction). The first height may be greater than the first width. For example, the first height may be about 2 to 10 times the first width. Bottom portions of the plurality of channel layers 430 may function as first source/drain areas, upper portions of the plurality of channel layers 430 may function as second source/drain areas, and parts of the plurality of channel layers 430 between the first source/drain areas and the second source/drain areas may function as channel areas.

In example embodiments, each of the plurality of channel layers 430 may include an oxide semiconductor, e.g., InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination of the above materials. Each of the plurality of channel layers 430 may include a single layer or a multilayer of the oxide semiconductor. In some embodiments, the plurality of channel layers 430 may have band gap energy greater than band gap energy of silicon. For example, the plurality of channel layers 430 may have band gap energy of about 1.5 eV to about 5.6 eV. For example, the plurality of channel layers 430 may have optimal channel performance when the plurality of channel layers 430 have band gap energy of about 2.0 eV to about 4.0 eV. For example, the plurality of channel layers 430 may be polycrystalline or amorphous. In example embodiments, the plurality of channel layers 430 may include a two-dimensional semiconductor material, e.g., graphene, carbon nanotube, or a combination of the above materials.

A first sub-gate electrode 440P1 and a second sub-gate electrode 440P2 of each of the plurality of gate electrodes 440 may extend on side walls of each of the plurality of channel layers 430 in the first horizontal direction (the X direction). Each of the plurality of gate electrodes 440 may include the first sub-gate electrode 440P1 facing a first side wall of each of the plurality of channel layers 430 and the second sub-gate electrode 440P2 facing a second side wall opposite to the first side wall of each of the plurality of channel layers 430. As one channel layer 430 is arranged between the first sub-gate electrode 440P1 and the second sub-gate electrode 440P2, the semiconductor memory device 2 may have a dual gate transistor structure. The second sub-gate electrode 440P2 may be omitted and only the first sub-gate electrode 440P1 facing the first side wall of each of the plurality of channel layers 430 may be formed so that a single gate transistor structure may be implemented.

Each of the plurality of gate electrodes 440 may include doped polysilicon, a metal, conductive metal nitride, conductive metal silicide, conductive metal oxide, or a combination of the above materials. For example, each of the plurality of gate electrodes 440 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination of the above materials.

Two adjacent gate insulating layers among the plurality of gate insulating layers 450 may surround the side walls of each of the plurality of channel layers 430 and may be interposed between each of the plurality of channel layers 430 and each of the plurality of gate electrodes 440. For example, as illustrated in FIG. 12, the side walls of each of the plurality of channel layers 430 may be surrounded by the two adjacent gate insulating layers among the plurality of gate insulating layers 450 and parts of side walls of each of the plurality of gate electrodes 440 may contact the two adjacent gate insulating layers among the plurality of gate insulating layers 450. In other embodiments, the plurality of gate insulating layers 450 may extend in a direction (that is, the first horizontal direction (the X direction)) in which the plurality of gate electrodes 440 extend and only two side walls of each of the plurality of channel layers 430, which face each of the plurality of gate electrodes 440, may contact each of the plurality of gate insulating layers 450.

In example embodiments, each of the plurality of gate insulating layers 450 may include a silicon oxide layer, a silicon oxynitride layer, a high-k dielectric layer having a dielectric constant higher than that of a silicon oxide layer, or a combination of the above layers. The high-k dielectric layer may include metal oxide or metal oxynitride. For example, the high-k dielectric layer used as each of the plurality of gate insulating layers 450 may include HfO₂, HfSiO, HfSiON, HfTaO, HfSiO, HfZrO, ZrO₂, Al₂O₃, or a combination of the above materials.

On the plurality of first insulating patterns 422, a plurality of second insulating patterns 432 may extend in the second horizontal direction (the Y direction) and each of the plurality of channel layers 430 may be arranged between two adjacent second insulating patterns 432 among the plurality of second insulating patterns 432. In addition, between the two adjacent second insulating patterns 432, each of a plurality of first buried layers 434 and each of a plurality of second buried layers 436 may be arranged in a space between two adjacent channel layers 430. Each of the plurality of first buried layers 434 may be arranged on a bottom surface of the space between the two adjacent channel layers 430 and each of a plurality of second buried layers 436 may fill a remaining part of the space between the two adjacent channel layers 430 on each of the plurality of first buried layers 434. An upper surface of each of the plurality of second buried layers 436 may be at the same level as an upper surface of each of the plurality of channel layers 430 and the plurality of second buried layers 436 may cover upper surfaces of the plurality of gate electrodes 440. Unlike in the above, the plurality of second insulating patterns 432 may include material layers continuous to the plurality of first insulating patterns 422 or the plurality of second buried layers 436 may include material layers continuous to the plurality of first buried layers 434.

A plurality of capacitor contacts 460 may be arranged on the plurality of channel layers 430. The plurality of capacitor contacts 460 may be arranged to vertically overlap the plurality of channel layers 430 and may be arranged in a matrix to be spaced apart from one another in the first horizontal direction (the X direction) and the second horizontal direction (the Y direction). Each of the plurality of capacitor contacts 460 may include doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination of the above materials. Two adjacent upper insulating layers among a plurality of upper insulating layers 462 may surround side walls of each of the plurality of capacitor contacts 460 on two adjacent second insulating patterns among the plurality of second insulating patterns 432 and two adjacent buried layers among the plurality of second buried layers 436.

A plurality of etch stop layers 470 may be arranged on the plurality of upper insulating layers 462 and a capacitor structure 500 may be arranged on the plurality of etch stop layers 470. The capacitor structure 500 may include a plurality of lower electrodes 510, a capacitor dielectric layers 520, and an upper electrode 530.

The plurality of lower electrodes 510 may be electrically connected to upper surfaces of the plurality of capacitor contacts 460 through the plurality of etch stop layers 470. Each of the plurality of lower electrodes 510 may be in the form of a pillar extending in the third direction (the Z direction). In example embodiments, the plurality of lower electrodes 510 may be arranged to vertically overlap the plurality of capacitor contacts 460 and may be arranged in a matrix to be spaced apart from one another in the first horizontal direction (the X direction) and the second horizontal direction (the Y direction). Unlike in the above, a plurality of landing pads may be further arranged between the plurality of capacitor contacts 460 and the plurality of lower electrodes 510 so that the plurality of lower electrodes 510 may be hexagonal.

The plurality of lower electrodes 510 and the upper electrode 530 may be the plurality of lower electrodes 210 and the upper electrodes 230 illustrated in FIGS. 3A to 10 and the capacitor dielectric layers 520 may be one of the capacitor dielectric layers 220, 220a, 220b illustrated in FIGS. 3A to 10.

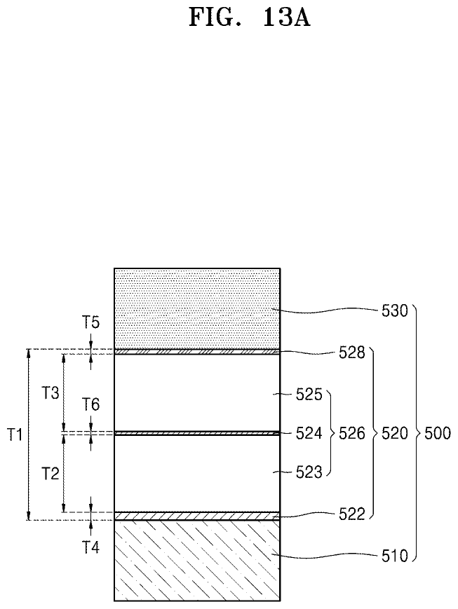

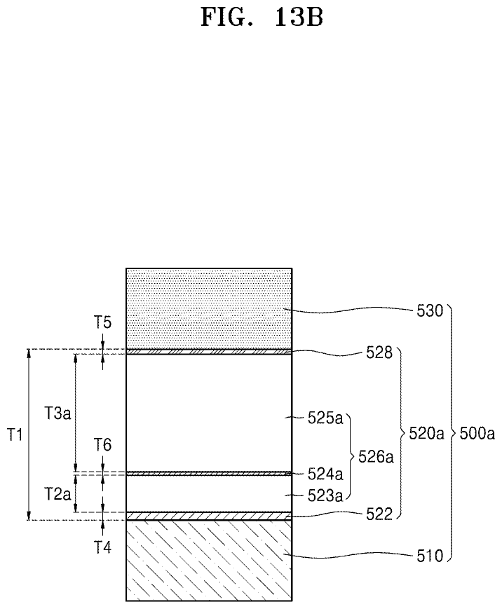

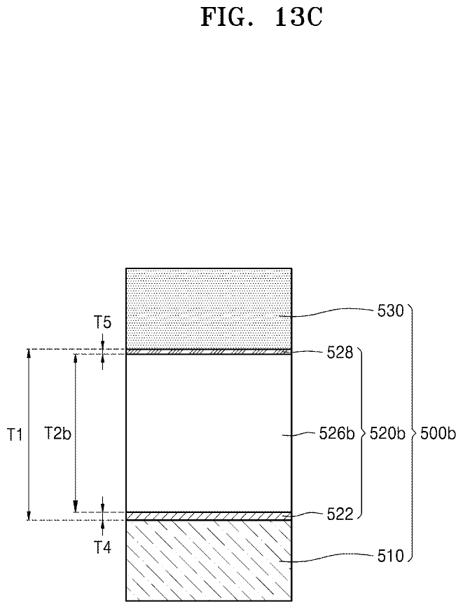

Each of FIGS. 13A to 13C is a cross-sectional view of a capacitor structure in a semiconductor memory device, according to embodiments. Particularly, FIG. 13A is an enlarged cross-sectional view of part XIII of FIG. 12, and each of FIGS. 13B and 13C is an enlarged cross-sectional view of a part corresponding to the part XIII of FIG. 12.

Referring to FIGS. 11 to 13A, the semiconductor memory device 2 may include the plurality of capacitor structures 500 including the plurality of lower electrodes 510, the capacitor dielectric layer 520, and the upper electrode 530. The capacitor dielectric layer 520 may have a stack structure including a lower interface layer 522, a dielectric structure 526, and an upper interface layer 528. The lower interface layer 522 may be between the dielectric structure 526 and the lower electrode 510, the upper interface layer 528 may be between the dielectric structure 526 and the upper electrode 530, and the dielectric structure 526 may be between the lower interface layer 522 and the upper interface layer 528. The dielectric structure 526 may have a stack structure including a lower dielectric layer 523, an upper dielectric layer 525, and an insertion layer 524 between the lower dielectric layer 523 and the upper dielectric layer 525.

The dielectric structure 526 including the lower dielectric layer 523, the upper dielectric layer 525, and the insertion layer 524, and the capacitor dielectric layer 520 including the lower interface layer 522 and the upper interface layer 528 are substantially the same as the dielectric structure 226 including the lower dielectric layer 223, the upper dielectric layer 225, and the insertion layer 224, and the capacitor dielectric layer 220 including the lower interface layer 222 and the upper interface layer 228, and thus a detailed description thereof is omitted herein.

Referring to FIGS. 11, 12, and 13B, the semiconductor memory device 2 may include a plurality of capacitor structure 500a shown in FIG. 13B instead of the plurality of capacitor structure 500. The plurality of capacitor structure 500a may include the plurality of lower electrodes 510, a capacitor dielectric layer 520a, and the upper electrode 530. The capacitor dielectric layer 520a may have a stack structure including the lower interface layer 522, a dielectric structure 526a, and the upper interface layer 528. The lower interface layer 522 may be between the dielectric structure 526a and the lower electrode 510, the upper interface layer 528 may be between the dielectric structure 526a and the upper electrode 530, and the dielectric structure 526a may be between the lower interface layer 522 and the upper interface layer 528. The dielectric structure 526a may have a stack structure including a lower dielectric layer 523a, an upper dielectric layer 525a, and an insertion layer 524a between the lower dielectric layer 523a and the upper dielectric layer 525a.

The dielectric structure 526a including the lower dielectric layer 523a, the upper dielectric layer 525a, and the insertion layer 524a, and the capacitor dielectric layer 520a including the lower interface layer 522 and the upper interface layer 528 are substantially the same as the dielectric structure 226a including the lower dielectric layer 223a, the upper dielectric layer 225a, and the insertion layer 224a, and the capacitor dielectric layer 220a including the lower interface layer 222 and the upper interface layer 228, and thus a detailed description thereof is omitted herein.

Referring to FIGS. 11, 12, and 13C, the semiconductor memory device 2 may include a plurality of capacitor structure 500b shown in FIG. 13C instead of the plurality of capacitor structure 500. The plurality of capacitor structures 500b may include the plurality of lower electrodes 510, a capacitor dielectric layer 520b, and the upper electrode 530. The capacitor dielectric layer 520b may have a stack structure including the lower interface layer 522, a dielectric structure 526b, and the upper interface layer 528. The lower interface layer 522 may be between the dielectric structure 526b and the lower electrode 510, the upper interface layer 528 may be between the dielectric structure 526b and the upper electrode 530, and the dielectric structure 526b may be between the lower interface layer 522 and the upper interface layer 528.

The dielectric structure 526b and the capacitor dielectric layer 520b including the lower interface layer 522 and the upper interface layer 528 are substantially the same as the dielectric structure 226b and the capacitor dielectric layer 220b including the lower interface layer 222 and the upper interface layer 228, and thus a detailed description thereof is omitted herein.

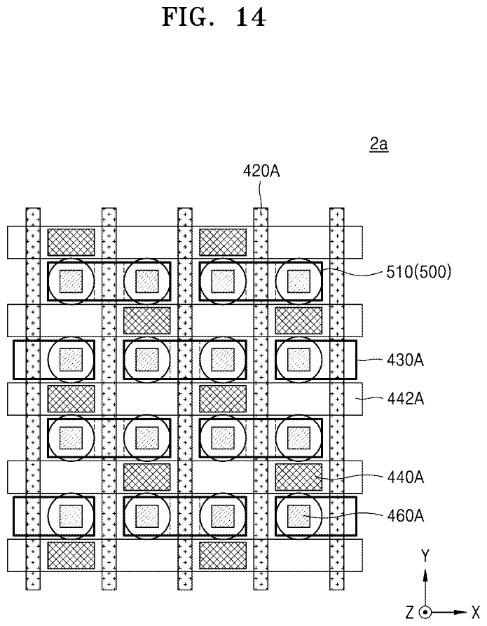

FIG. 14 is a layout diagram illustrating a semiconductor memory device 2a and

FIG. 15 is a perspective view illustrating a semiconductor memory device.

Referring to FIGS. 14 and 15, the semiconductor memory device 2a may include a substrate 410A, a plurality of first conductive lines 420A, a plurality of channel structures 430A, a plurality of contact gate electrodes 4440A, a plurality of second conductive lines 442A, and the plurality of capacitor structures 500. The semiconductor memory device 2a may be a memory device including a VCT.

In the substrate 410A, a plurality of active areas AC may be defined by a plurality of first isolation layers 412A and a plurality of second isolation layers 414A. The plurality of channel structures 430A may be respectively arranged in the plurality of active areas AC and may respectively include a plurality of first active pillars 430A1 and a plurality of second active pillars 430A2 extending in a vertical direction and a plurality of connection units 430L connected to bottom surfaces of the plurality of first active pillars 430A1 and bottom surfaces of the plurality of second active pillars 430A2. In the plurality of connection units 430L, a plurality of first source/drain areas SD1 may be arranged and, in upper portions of the plurality of first and second active pillars 430A1 and 430A2, a plurality of second source/drain areas SD2 may be arranged. Each of the plurality of first and second active pillars 430A1 and 430A2 may configure an independent unit memory cell.

The plurality of first conductive lines 420A may extend to intersect the plurality of active areas AC, e.g., in the second horizontal direction (the Y direction). One of the plurality of first conductive lines 420A may be arranged on each of the plurality of connection units 430L between each of the plurality of first active pillars 430A1 and each of the plurality of second active pillars 430A2 and may be arranged on each of the plurality of first source/drain areas SD1. Another first conductive line 420A adjacent to the one first conductive line 420A may be arranged between two channel structures 430A. One of the plurality of first conductive lines 420A may function as a common bit line included in two unit memory cells configured by the first active pillar 430A1 and the second active pillar 430A2 arranged on both sides of the one first conductive lines 420A.

Between two channel structures 430A adjacent to each other in the second horizontal direction (the Y direction), a contact gate electrode 440A may be arranged. For example, the contact gate electrode 440A may be arranged between a first active pillar 430A1 included in a channel structure 430A and a second active pillar 430A2 of a channel structure 430A adjacent to the channel structure 430A and may be shared by the first active pillar 430A1 and the second active pillar 430A2 arranged on side walls of the contact gate electrode 440A. Between the contact gate electrode 440A and the first active pillar 430A1 and between the contact gate electrode 440A and the second active pillar 430A2, a gate insulating layer 450A may be arranged. A plurality of second conductive lines 442A may extend on upper surfaces of the plurality of contact gate electrodes 440A in the first horizontal direction (the X direction). The plurality of second conductive lines 442A may function as a plurality of word lines of the semiconductor memory device 2a.

A plurality of capacitor contacts 460A may be arranged on the plurality of channel structures 430A. The plurality of capacitor contacts 460A may be arranged on the plurality of second source/drain areas SD2 and the plurality of capacitor structures 500 may be arranged on the plurality of capacitor contacts 460A. The plurality of capacitor structures 500 may be one of the plurality of capacitor structures 500, 500a, and 500b illustrated in FIGS. 11 to 13c.

By way of summation and review, embodiments provide a semiconductor memory device in which the capacity of a capacitor may be secured. That is, a lower interface layer and an upper interface layer doped with different conductive types, i.e., n and p types, may be formed in portions of a capacitor dielectric layer respectively in contact with a lower electrode and an upper electrode. Therefore, because the capacitor dielectric layer has fixed polarization formed by the lower interface layer and the upper interface layer, a capacitance of a capacitor structure may increase, thereby securing the capacity of the capacitor.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A semiconductor memory device, comprising:
a substrate; and
a capacitor structure on the substrate, the capacitor structure including a lower electrode, a capacitor dielectric layer, and an upper electrode,
wherein the capacitor dielectric layer includes:
a lower interface layer on the lower electrode and doped with impurities of a first conductive type;
an upper interface layer beneath the upper electrode and doped with impurities of a second conductive type other than the first conductive type; and
a dielectric structure between the lower interface layer and the upper interface layer.

2. The semiconductor memory device as claimed in claim 1, wherein the first conductive type is n type, and the second conductive type is p type.

3. The semiconductor memory device as claimed in claim 1, wherein each of the lower interface layer and the upper interface layer includes a metal oxide, and the impurities of the first conductive type and the impurities of the second conductive type are atom ions.

4. The semiconductor memory device as claimed in claim 3, wherein a percentage of the impurities of the first conductive type among metal atoms included in the lower interface layer is less than 5 atomic %, and a percentage of the impurities of the second conductive type among metal atoms included in the upper interface layer is less than 5 atomic %.

5. The semiconductor memory device as claimed in claim 3, wherein a percentage of the impurities of the first conductive type among metal atoms included in the lower interface layer is greater than a percentage of the impurities of the second conductive type among metal atoms included in the upper interface layer.

6. The semiconductor memory device as claimed in claim 1, wherein a thickness of the lower interface layer is greater than a thickness of the upper interface layer.

7. The semiconductor memory device as claimed in claim 1, wherein the dielectric structure has a stack structure including a lower dielectric layer, an upper dielectric layer, and an insertion layer between the lower dielectric layer and the upper dielectric layer, and a bandgap of the insertion layer is greater than a bandgap of each of the lower dielectric layer and the upper dielectric layer.

8. The semiconductor memory device as claimed in claim 7, wherein a dielectric constant of the upper dielectric layer is greater than a dielectric constant of the lower dielectric layer.

9. The semiconductor memory device as claimed in claim 7, wherein a thickness of the upper dielectric layer is greater than a thickness of the lower dielectric layer.

10. The semiconductor memory device as claimed in claim 7, wherein a thickness of the insertion layer is less than a thickness of each of the lower interface layer and the upper interface layer.

11. A semiconductor memory device, comprising:
a substrate having a memory cell region; and
capacitor structures in the memory cell region of the substrate, the capacitor structures including lower electrodes, an upper electrode, and a capacitor dielectric layer between the lower electrodes and the upper electrode,
wherein the capacitor dielectric layer includes:
a lower interface layer doped with impurities of a first conductive type, a lower dielectric layer, an insertion layer, an upper dielectric layer, and an upper interface layer doped with impurities of a second conductive type other than the first conductive type, which are sequentially stacked on the lower electrode, and a bandgap of the insertion layer is greater than each of a bandgap of the lower dielectric layer and a bandgap of the upper dielectric layer.

12. The semiconductor memory device as claimed in claim 11, wherein each of the lower interface layer and the upper interface layer includes metal oxide, the impurities of the first conductive type and the impurities of the second conductive type are atom ions, and each of a percentage of the impurities of the first conductive type among metal atoms included in the lower interface layer and a percentage of the impurities of the second conductive type among metal atoms included in the upper interface layer is less than 5 atomic %.

13. The semiconductor memory device as claimed in claim 11, wherein a thickness of the lower interface layer is greater than or equal to a thickness of the upper interface layer.

14. The semiconductor memory device as claimed in claim 11, wherein a thickness of the lower interface layer is less than a thickness of the upper interface layer.

15. The semiconductor memory device as claimed in claim 11, wherein a thickness of each of the lower interface layer and the upper interface layer is about 10 Å or less, and a thickness of the insertion layer is about 5 Å or less.

16. The semiconductor memory device as claimed in claim 11, wherein the capacitor dielectric layer includes a material having an antiferroelectricity characteristic, a material having a ferroelectricity characteristic, or a material in which the antiferroelectricity characteristic is combined with the ferroelectricity characteristic.

17. The semiconductor memory device as claimed in claim 11, wherein the upper dielectric layer has a dielectric constant greater than a dielectric constant of the lower dielectric layer and has a thickness greater than a thickness of the lower dielectric layer.

18. A semiconductor memory device, comprising:
a substrate having active regions in a memory cell region;
buried contacts connected to the active regions;
landing pads on the buried contacts; and
capacitor structures in the memory cell region of the substrate and including lower electrodes electrically connected to the landing pads, an upper electrode, and a capacitor dielectric layer between the lower electrodes and the upper electrode,
wherein the capacitor dielectric layer includes a lower interface layer that is a metal oxide doped with n-type impurities that are metal atoms, a lower dielectric layer, an insertion layer, an upper dielectric layer, and an upper interface layer that is a metal oxide doped with p-type impurities that are metal atoms, which are sequentially stacked on the lower electrode, a thickness of the lower interface layer being greater than a thickness of the upper interface layer, and a thickness of the insertion layer being less than the thickness of the upper interface layer.

19. The semiconductor memory device as claimed in claim 18, wherein a bandgap of the insertion layer is greater than each of a bandgap of the lower dielectric layer and a bandgap of the upper dielectric layer, and a thickness of the upper dielectric layer is greater than a thickness of the lower dielectric layer.

20. The semiconductor memory device as claimed in claim 18, wherein a thickness of the capacitor dielectric layer is about 30 Å to about 60 Å, the thickness of the lower interface layer is about 10 Å or less, the thickness of the upper interface layer is about 7 Å or less, and the thickness of the insertion layer is about 5 Å or less.
